(19) United States
(12) Patent Application Publication
(10) Pub. No.: US 2010/0295138 A1
(43) Pub. Date: Nov. 25, 2010

(54) METHODS AND SYSTEMS FOR FABRICATION OF MEMS CMOS DEVICES

(75) Inventors: Josep Montanya Silvestre, Rubi (ES); Juan Jose Valle Fraga, Burela (ES); Marco Antonio Llamas Morote, Viladecans (ES); Tayyib Sabir, Ely (GB)

Correspondence Address: ROPES & GRAY LLP, PATENT DOCKETING 39/41, ONE INTERNATIONAL PLACE, BOSTON, MA, 02110-2624, US

(73) Assignee: Baolab Microsystems SL, Terrassa (ES)

(21) Appl. No.: 12/784,024

(22) Filed: May 20, 2010

Related U.S. Application Data
(60) Provisional application No. 61/311,997, filed on Mar. 9, 2010.
(60) Provisional application No. 61/312,017, filed on Mar. 9, 2010.
(60) Provisional application No. 61/312,027, filed on Mar. 9, 2010.
(60) Provisional application No. 61/312,034, filed on Mar. 9, 2010.

(30) Foreign Application Priority Data
May 20, 2009 (ES) P200901282

(51) Int. Cl. H01L 29/84; H01L 21/306

(52) U.S. Cl. 257/415; 438/50; 257/E21.215; 257/E29.324

(57) ABSTRACT

A MEMS integrated circuit including a plurality of layers where a portion includes one or more electronic elements on a semiconductor material substrate. The circuit includes a structure of interconnection layers having a bottom layer of conductor material and a top layer of conductor material where the layers are separated by at least one layer of dielectric material. The bottom layer may be formed above and in contact with an Inter Dielectric Layer. The circuit also includes a hollow space within the structure of interconnection layers and a MEMS device in communication with the structure of interconnection layers.

### CROSS REFERENCE TO RELATED APPLICATIONS

This application claims priority to Spanish Patent Application No. P200901282 filed May 20, 2009, entitled “Chip Comprising a MEMS Arranged in an Integrated Circuit and Corresponding Manufacturing Method”, hereby incorporated by reference in its entirety. This application also claims priority to U.S. Provisional Patent Application No. 61/311,997 filed Mar. 9, 2010, entitled “Methods and Systems for Fabrication of MEMS CMOS Devices”; U.S. Provisional Patent Application No. 61/312,017 filed Mar. 9, 2010, entitled “MEMS CMOS Vibrating Antenna and Fabrication Thereof”; U.S. Provisional Patent Application No. 61/312,027 filed Mar. 9, 2010, entitled “MEMS CMOS Integrated Inductor and Fabrication Thereof”; and U.S. Provisional Patent Application No. 61/312,034 filed Mar. 9, 2010, entitled “MEMS CMOS Modal Switch and Fabrication Thereof”, hereby incorporated by reference in their entireties.

### BACKGROUND OF THE INVENTION

An integrated circuit is a semiconductor device that has a substrate of a semiconductor material on which a series of layers are deposited using photolithographic techniques. The layers are doped, polarized and attacked, so that electrical elements (e.g., resistances, capacitors, or impedances) or electronic elements (e.g., diodes or transistors) are produced. Subsequently other layers are deposited, which form the structure of interconnection layers necessary for electrical connections.

The substrate may be made of a material from a group including Si, Ge, SiGe, GaAs, GaN or sapphire. The chip may be made using a technology from a group including MOSFET, bipolar or BiCMOS. MOSFET technology may include CMOS, PMOS, NMOS, UltraCMOS, SOI, and SOS variants.

Micro-electro-mechanisms or micro-electro-mechanical systems (MEMS) are small electro-mechanical devices made using layer deposition technologies based on photolithographic techniques. MEMS may provide cavities or hollow spaces in the inside thereof, which may be filled with liquids or gases. While conventional integrated circuits are completely solid devices, i.e., without any kind of hollows. Hollows may be defined as cavities that are larger than hollows on the atomic or subatomic scale. In some embodiments, MEMS may have mobile elements inside them. The mobile elements may be joined by one of the ends thereof to the rest of the MEMS structure, or may be completely loose (i.e., not physically attached to its surroundings) inside a housing that is at least partially closed (to prevent the loose part from “escaping” from the MEMS).

A chip may include a MEMS device and an integrated circuit, where the integrated circuit may control the MEMS. There are various techniques for manufacturing a chip that includes both a MEMS and an integrated circuit. One technique consists of manufacturing one element on top of the other. Another technique consists of joining the two elements (the MEMS and the integrated circuit) on a common substrate according to various means in a multi-chip module (MCM) package. Certain entities have developed techniques for manufacturing CMOS MEMS devices. A common technique for manufacturing CMOS MEMS devices is to perform a two-step process including: 1) anisotropic etching of trench outside of the target MEMS location, and then 2) isotropic etching of the Si substrate. Typically, the process involves using a hole or trench formed by step 1 where the trench or hole must be aligned outside the area where the MEMS is formed and performing line of sight etching to form the MEMS component using SF6. This process requires modification of and additional steps to a standard CMOS fabrication process.

None of these existing techniques seem particularly cost-effective, efficient, or suitable for mass or parallel production, as used for chips on a wafer. Existing CMOS MEMS fabrication techniques suffer from limited connections between the MEMS and the integrated circuit, degraded radio frequency properties, poor unit performance, and high cost. Additionally, existing CMOS MEMS typically have an accuracy of approximately 1 micron, and it is very difficult to reduce this precision rate.

Accordingly, there is a need for a more efficient, cost-effective, robust, reliable, scalable, and less disruptive process for fabricating CMOS MEMS devices.

### SUMMARY OF THE INVENTION

The invention addresses deficiencies in the prior art by enabling the fabrication and use of MEMS-based or other integrated chip devices in a more cost-efficient, robust, and scalable manner without the limitations of existing MEMS or other chip-based technologies.

Certain processes disclosed herein address a fundamental technical problem with manufacturing CMOS MEMS devices by enabling formation of a MEMS element within the interconnect layers of a chip using highly reactive etchant gases such as vapor hydrogen fluoride (HF) in a reliably, repeatable, and scalable manner.

While others have developed various CMOS MEMS fabrication techniques, no one has realized a way to robustly and reliably fabricate a CMOS MEMS chip using vapor HF (vHF) to etch the MEMS component within the interconnect layers. Unless the vapor HF etching process is carefully controlled, the etching process is susceptible to a run-away reaction where an excessive portion of a chip is etched and/or the MEMS component is damaged or destroyed. Existing fabrication techniques do not address this problem and existing CMOS MEMS manufacturers have typically avoided using vapor HF for this reason. Typically, current manufacturers use a two-step process of: 1) anisotropic etching of trench outside of the target MEMS location, and then 2) isotropic etching of the Si substrate. Instead of using vapor HF, manufacturers typically use SF6 for line-of-site etching from a trench or hole formed outside of the MEMS location. These existing approaches require a modification of the existing CMOS fabrication process including additional steps to the CMOS process.

By more carefully controlling the vapor HF etching process, the present inventive techniques eliminate the need for additionally and more costly fabrication steps or modifications of the standard CMOS fabrication process. For example, a CMOS chip typically includes an inter dielectric layer (ILD) between the silicon substrate and the interconnect layers. To prevent excessive etching of the ILD or silicon substrate, an conductor layer (or conductive metal layer), which is resistant to vapor HF, can be positioned between the ILD and interconnect layers to prevent excessive etching by the vapor HF of the ILD and/or substrate. A conductor layer may be positioned above the MEMS component and include one or more holes, aligned above a MEMS component, that allow for the passage of vapor HF into one or more interconnect layers to effect the release of the MEMS component.

Such techniques may be employed so that the vapor HF is controlled, making the vapor HF etching process within one or more interconnect layers more controllable. Other features and/or techniques may be employed to control the vapor HF etching process. For example, one or more vias may be used to limit and/or confine the vapor HF to a particular region or area of the interconnect layers. A standard vias, which consists of a stacked or segmented vias, cannot effectively block vapor HF from passing through cracks or gaps between its segments. However, the present invention, in certain features, employs a continuous via that is not segmented and, therefore, has no gaps or cracks to allow vapor HF to pass. No one has considered using a continuous via before. In fact, the fabrication of a continuous via is considered a design violation by a typical CMOS fabrication foundry. The Applicant, however, has recognized the synergistic effect of combining vapor HF etching in the interconnect layers while controlling such vapor HF etching using a continuous vias to enable a more cost-effective and robust CMOS MEMS fabrication process.

A top layer of the conductor material used to form the CMOS MEMS device may include one or more holes to allow the vapor HF to pass through, while inhibiting other gases or materials to pass through. Instead of having to position a hole or trench outside the area of the MEMS, the present application enables the one or more holes to be aligned above the MEMS because the vapor HF etching process can be controlled. Thus, enabling a more efficient and less intrusive post CMOS fabrication technique for releasing the MEMS as opposed to a two step process where hole must be formed outside the MEMS structure to enable line-of-site etching. More than one top conductor layer may also be used where each layer includes holes that are not aligned vertically. In this arrangement, when the holes are sealed, the offset arrangement of holes between layers inhibits the sealing material from reaching or affecting the MEMS.

Other inventive techniques and/or features may be employed to control the vapor HF etching process in the interconnect layers. For example, using a passivation layer including a layer of silicon rich nitride. A layer of silicon nitride rich in silicon is more resistant to attack with HF. Thus, the layer of silicon nitride rich in silicon leaves less residue on attack with HF. The Si content can be determined by the refractive index (RI) of the layer of silicon nitride. By selectively choosing a passivation layer having an RI in the range of about 1.8 to 2.8, the vapor HF etching process can be controlled, including controlling the duration of vapor HF etching. Depending on the amount of vapor HF etching, excessive residue may be formed that could substantially degrade the performance of the resulting device. Accordingly, the applicant has realized that applying the appropriate temperature for the appropriate period of time, e.g., 110° C., enables the removal of adverse residue from the etching process. Various temperatures over the range of about 100° C. to about 250° C. may be used to enable varying amounts of the residue removal.

The inventive CMOS MEMS vapor HF fabrication process in the interconnect layers may be used to fabricate, without limitation, various devices such as capacitors, mechanical capacitors, inductors, vibrating antennas, sensors, switches, and memory. One type of switch may include a modal switch whereby the transmission of a signal can be controlled by controlling the mode of transmission. For example, a signal transmission system may include a first signal medium arranged to transmit an electrical signal using one of a first transmission mode and a second transmission mode, a second signal medium arranged to transmit an electrical signal using the first transmission mode, and a controller arranged to set the mode of the of the first signal medium to one of the first transmission mode and the second transmission mode.

While various inventive concepts, features, and methods are described as follows, Applicant has contemplated all of the various combinations of dependents steps or features that may be utilized including different combinations of dependent features or steps for a particular aspect (including dependent features or steps listed in the claims), or various combinations of dependent steps or features among and between various aspects (including dependent features or steps listed in the claims). The skilled person will recognize that Applicant has contemplated and provided sufficient disclosure for support of any of the various combinations of features in and among the various aspects.

In one aspect, a MEMS integrated circuit includes a plurality of layers where a portion includes one or more electronic elements on a semiconductor material substrate. The circuit also includes a structure of interconnection layers having a bottom layer of conductor material and a top layer of conductor material where the layers are separated by at least one layer of dielectric material. The circuit further includes a hollow space within the structure of interconnection layers and a MEMS device in communication with the structure of interconnection layers. The at least one bottom layer of conductor material may include a bottom layer of conductor material formed above and in contact with an Inter Level Dielectric (ILD) layer.

In another aspect, further refinements or enhancements to the MEMS integrated circuit, and related fabrication techniques are disclosed. Additional or substitute stages that may be required in the manufacturing process are also described. In some embodiments, the plurality of layers of the MEMS integrated circuit may be stacked together to form an equivalent thicker metal layer. In some embodiments, the MEMS device may be attached to the structure of the interconnection layers via a soft spring. In some embodiments, the MEMS device comprises a part that is detached from the MEMS structure and is mechanically free. In some embodiments, horizontal and/or vertical continuous vias may be used as partitions of HF resistant material around the MEMS. In some embodiments, the MEMS device may include a multi-level memory, programmed by changing the resistance value (e.g., by overpassing the electromigration limit for a limited period of time) of a via in a cell of the memory. In some embodiments, chemical-mechanical polishing may be performed on a passivation layer of the MEMS integrated circuit. In some embodiments, passivation may be performed on scribes lines of the wafer on which the circuit is formed. In some embodiments, a layer of single oxide dielectric material may be used. In some embodiments, Al sputtering may be performed when sealing the MEMS integrated circuit after etching.

In yet another aspect of the invention, a MEMS integrated circuit including a plurality of layers where a portion includes one or more electronic elements on a semiconductor material substrate. The circuit includes a structure of interconnection layers having a bottom layer of conductor material and a top layer of conductor material where the layers are separated by at least one layer of dielectric material. The circuit also includes a hollow space within the structure of interconnection layers and a capacitive sensor in communication with the structure of interconnection layers.

In still another aspect, various applications of an integrated circuit capacitive sensor are described that are not necessarily limited to MEMS technology. In some configurations, a CMOS MEMS device includes a capacitive sensor that may be configured to operate as a vibrating antenna, an accelerometer, a magnetometer, a gyroscope, and/or a compass. In one configuration, a vibrating antenna including a capacitive sensor is operated at relatively high frequencies, such as in a cellular telephone frequency range. In a further configuration, a capacitive sensor and/or element in a vibrating antenna may be utilized and modified to achieve better sensitivity by using a mechanically resonant structure, where the antenna vibrates at its mechanical resonant frequency.

In still another aspect, an integrated circuit may include a capacitive sensor operating in a first mode as an accelerometer, a magnetometer, a gyroscope, or a compass at a first time, but then operate in a second mode as an accelerometer, a magnetometer, a gyroscope, or a compass at a second time.

In yet another aspect, an integrated circuit includes the integration of large inductors with good quality factors. In conventional discrete element electronics, inductors may be implemented as solenoids. This allows for good coupling between some or all of the inductor coils. As a result, it may be possible to use a reasonable conductor width to minimize resistive losses. However, in the field of microelectronics, it may not be feasible to implement inductors as solenoids due to their dimensions. For example, there is no vertical space to place these coils vertically. Otherwise, the area of each coil would be negligible. It may be undesirable to use vias as they are largely resistive, and the number of turns implemented vertically may be limited. Planar inductors may be implemented instead. However, planar inductors may suffer from large losses (which leads to low Q) due to reduced section wire and coupling through the substrate. In addition, the achieved inductance value, L, may be low because the loop area reduces at each turn, leading to weak coupling.

In yet another aspect, a MEMS integrated circuit includes a plurality of layers where a portion includes one or more electronic elements on a semiconductor material substrate. The circuit also includes a structure of interconnection layers having a bottom layer of conductor material and a top layer of conductor material where the layers are separated by at least one layer of dielectric material. The circuit further also includes a hollow space within the structure of interconnection layers and an integrated inductor in communication with the structure of interconnection layers.

In some embodiments, a modal or multimodal switch replaces an ohmic contact switch in uniplanar transmission lines. A modal switch instead of cutting or bouncing power at a given point, transfers from one mode to another. If a section of the transmission line does not allow one of the modes, then transferring to that mode is equivalent to cutting the signal. In some embodiments, the modal switch is a transition between two types of uniplanar transmission lines, coplanar waveguides (CPWs) and slotlines. The modal switch includes a tunable structure implemented as an asymmetric load on the transmission line. This structure acts like a tunable impedance, implemented in an ohmic configuration, or a capacitive configuration, or a combination of both. The tunable structure may transfer power from one mode to another, or cut power, dependent on the modes allowed in the transmission line.

In yet another aspect, a signal transmission system including a first signal medium arranged to transmit an electrical signal using one of a first transmission mode and a second transmission mode and a second signal medium arranged to transmit an electrical signal using the first transmission mode. The system may also include a controller, e.g., a modal switch, arranged to set the mode of the of the first signal medium to one of the first transmission mode and the second transmission mode to enable or block the transmission of a signal from the first to second signal medium. The system may be formed in a integrated circuit such as a CMOS integrated circuit or MEMS CMOS integrated circuit.

In still another aspect, a MEMS integrated circuit includes a plurality of layers where a portion includes one or more electronic elements on a semiconductor material substrate. The circuit also includes a structure of interconnection layers having a bottom layer of conductor material and a top layer of conductor material where the layers are separated by at least one layer of dielectric material. The circuit further includes a hollow space within the structure of interconnection layers and a modal switch in communication with the structure of interconnection layers.

In still another aspect, a MEMS integrated circuit includes a plurality of layers where a portion includes one or more electronic elements on a semiconductor material substrate. The circuit also includes a structure of interconnection layers having a bottom layer of conductor material and a top layer of conductor material where the layers are separated by at least one layer of dielectric material. The circuit further includes a hollow space within the structure of interconnection layers and mechanical capacitor in communication with the structure of interconnection layers.

### BRIEF DESCRIPTION OF THE DRAWINGS

Other advantages and characteristics of the invention may be appreciated from the following description, which provides a non-limiting description of embodiments of the invention, with reference to the accompanying drawings, in which:

FIG. 1 is a diagrammatical view of a cross section of a first embodiment of a chip according to the invention.

FIG. 2 is a diagrammatical view of a cross section of a second embodiment of a chip according to the invention,

FIG. 3 is the chip of FIG. 2 after the stage of producing a new sealing layer.

FIG. 4 is a diagrammatical view of a cross section of a third embodiment of a chip according to the invention.

FIG. 5 is a diagrammatic view of a cross section of a fourth embodiment of a chip according to the invention, before an HF attack.

FIG. 6 is a diagrammatic view of a cross section of a fourth embodiment of a chip according to the invention, after an HF attack.

FIG. 7 is a diagrammatic view of a cross section of a fifth embodiment of a chip according to the invention, showing an HF attack on a sublayer of silicon oxide being more pronounced than on a sublayer of silicon nitride.

FIG. 8 is a diagrammatic view of a cross section of a fifth embodiment of a chip according to the invention, showing a cantilever break in an uncontrolled way.

FIG. 9 is a diagrammatic view of a cross section of a chip, showing the passivation layer consisting of two different masks according to an illustrative embodiment of the invention.

FIG. 10 is a diagrammatic view of a cross section of a chip showing lack of direct contact between HF and a silicon oxide sublayer due to a wrapping of a silicon nitride sublayer according to an illustrative embodiment of the invention.

FIG. 11A shows a diagrammatic view of a structure with three thin metal layers, without stacking, before release from oxide according to an illustrative embodiment of the invention.

FIG. 11B shows a diagrammatic view of a structure with three thin metal layers, without stacking, after release from oxide according to an illustrative embodiment of the invention.

FIG. 12A shows a diagrammatic view of a structure with three thin metal layers stacked together before release from oxide according to an illustrative embodiment of the invention.

FIG. 12B shows a diagrammatic view of a structure with three thin metal layers stacked together after release from oxide according to an illustrative embodiment of the invention.

FIG. 13A shows a diagrammatic top view of an o-shaped spring according to an illustrative embodiment of the invention.

FIG. 13B shows a diagrammatic top view of an o-shaped spring according to another illustrative embodiment of the invention.

FIG. 14A shows a diagrammatic top view of a spring with multiple meanders according to an illustrative embodiment of the invention.

FIG. 14B shows a diagrammatic top view of a spring with multiple meanders according to another illustrative embodiment of the invention.

FIG. 15 shows a 64-node multi-level memory according to an illustrative embodiment of the invention.

FIG. 16A shows a substrate with continuous vias used as partitions of HF resistant material according to an illustrative embodiment of the invention.

FIG. 16B shows a stack of multiple vias where each section may be associated with a layer of an integrated circuit.

FIG. 16C shows a continuous via used as partitions of HF resistant material according to an illustrative embodiment of the invention.

FIG. 16D shows a cross-section of a one-wall scheme for a continuous via according to an illustrative embodiment of the invention.

FIG. 16E shows a cross-section of a two-wall scheme for a continuous via according to an illustrative embodiment of the invention.

FIG. 16F shows a cross-section of a two-wall scheme continuous via after etching with vaporized HF, according to an illustrative embodiment of the invention.

FIG. 16G shows a cross-section of a three-wall scheme for a continuous via according to an illustrative embodiment of the invention.

FIG. 16H shows a Scanning Electron Microscope (SEM) image after release of a continuous via according to an illustrative embodiment of the invention.

FIG. 17 shows a diagrammatic view of a cross section of an embodiment of a chip according to the invention, after a process flow step of Al sputtering.

FIG. 18 shows a diagrammatic view of a cross section of an embodiment of a chip according to the invention, after another process flow step of Al sputtering.

FIG. 19 shows a diagrammatic view of a cross section of an embodiment of a chip according to the invention, after yet another process flow step of Al sputtering.

FIG. 20 shows a diagrammatic view of a cross section of an embodiment of a chip according to the invention, after yet another process flow step of Al sputtering.

FIG. 21 shows a diagrammatic view of a cross section of an embodiment of a chip according to the invention, after yet another process flow step of Al sputtering.

FIG. 22 shows a diagrammatic view of a cross section of an embodiment of a chip according to the invention, after yet another process flow step of Al sputtering.

FIG. 23 shows a diagrammatic view of a cross section of an embodiment of a chip according to the invention, after yet another process flow step of Al sputtering.

FIG. 24A shows a diagrammatic view of a cross section of an embodiment of a chip according to the invention, after yet another process flow step of Al sputtering.

FIG. 24B shows a diagrammatic view of a cross section of an embodiment of a chip according to the invention, after yet another process flow step of Al sputtering.

FIG. 24C shows a diagrammatic view of a cross section of an embodiment of a chip according to the invention, after yet another process flow step of Al sputtering.

FIG. 24D shows a diagrammatic view of a cross section of an embodiment of a chip according to the invention, after yet another process flow step of Al sputtering.

FIG. 25 shows a finger switch according to an illustrative embodiment of the invention.

FIG. 26 shows a resonant capacitive antenna implemented as a MEMS device according to an illustrative embodiment of the invention.

FIG. 27 shows a top view of the resonant capacitive antenna implemented as a MEMS device according to an illustrative embodiment of the invention.

FIG. 28 shows the metal layer M1 of the resonant capacitive antenna implemented as a MEMS device according to an illustrative embodiment of the invention.

FIG. 29 shows a layout of a die containing integrated inductors according to an illustrative embodiment of the invention.

FIG. 30 shows a Scanning Electron Microscope (SEM) image after release of an integrated inductor according to an illustrative embodiment of the invention.

FIG. 31 shows an integrated transformer according to an illustrative embodiment of the invention.

FIG. 32A shows a modal switch according to an illustrative embodiment of the invention, in the OFF state.

FIG. 32B shows a modal switch according to an illustrative embodiment of the invention, in the ON state.

FIG. 33A is a diagrammatical top view of modal switch variable capacitors according to an illustrative embodiment of the invention, in the OFF state.

FIG. 33B is a diagrammatical top view of modal switch variable capacitors according to an illustrative embodiment of the invention, in the ON state.

FIG. 34 is a diagrammatical cross-sectional view of a variable capacitor implemented in a one-poly six-metal (1P6M) CMOS process with a metal insulator metal (MIM) structure according to an illustrative embodiment of the invention.

FIG. 35A shows a conventional MIM structure according to an illustrative embodiment of the invention.

FIG. 35B shows a MIM structure without a MIM top plate and a silicon nitride (SiN) layer with a refractive index (RI) of 2.5 according to an illustrative embodiment of the invention.

FIG. 35C shows a MIM structure without a MIM top plate and a SiN layer with an RI of 2.5 according to an illustrative embodiment of the invention.

FIG. 36 shows a MIM capacitive structure with high-k dielectric deposited on vertical walls according to an illustrative embodiment of the invention.

FIG. 37 shows a voltage-charge curve for an electric capacitor according to an illustrative embodiment of the invention.

FIG. 38 shows a voltage-charge curve for a mechanical capacitor according to an illustrative embodiment of the invention.

FIG. 39 shows a schema for a lateral mechanical capacitor design according to an illustrative embodiment of the invention.

FIG. 40 shows a schema for a lateral mechanical capacitor design according to another illustrative embodiment of the invention.

FIG. 41 shows a stretchable mechanical capacitor moveable plate according to an illustrative embodiment of the invention.

FIG. 42A shows a mechanical capacitor moveable plate comprising a set of deformable dimples where the capacitor plates are not touching, according to an illustrative embodiment of the invention.

FIG. 42B shows a mechanical capacitor moveable plate comprising a set of deformable dimples where the capacitor plates are touching, according to an illustrative embodiment of the invention.

FIG. 43A shows a top view of a variable gap mechanical capacitor with a moveable plate of varying thickness according to an illustrative embodiment of the invention.

FIG. 43B shows a lateral view of a variable gap mechanical capacitor with a moveable plate of varying thickness according to an illustrative embodiment of the invention.

FIG. 44 shows voltage-charge curves for mechanical filter devices according to an illustrative embodiment of the invention.

FIG. 45 shows the functioning of an exponential charge pump according to an illustrative embodiment of the invention.

FIG. 46 shows an illustrative embodiment of an exponential charge pump, implemented with two layers.

### DETAILED DESCRIPTION OF EMBODIMENTS

The application relates to a manufacturing method of a chip comprising a MEMS arranged in an integrated circuit, where the MEMS comprises at least one hollow space. The method comprising:

a) stages for producing layers that form electrical or electronic elements on a substrate made of semiconductor material, and

b) an interconnection stage, in which a structure of interconnection layers is made, which comprises depositing at least one bottom layer of conductor material and one top layer of conductor material separated by at least one layer of dielectric material.

The invention also relates to a chip comprising an integrated circuit, said integrated circuit comprising:

a) layers forming electrical or electronic elements on a substrate of semiconductor material,

b) a structure of interconnection layers, with at least one bottom layer of conductor material and one top layer of conductor material separated by at least one layer of dielectric material.

The invention addresses deficiencies in the prior art using a manufacturing method of a chip of the type indicated in the field of the invention, characterized in that after said interconnection stage b), a stage c) is performed comprising an attack using gaseous HF (hydrogen fluoride), wherein during the attack the hollow space (inter alia) of the MEMS is formed in the structure of interconnection layers.

In fact, this invention is aimed at fully integrating MEMS production in the integrated circuit production. The integrated circuit is produced following the sequence of normal relevant steps, and does not interfere at any time in either the quality or the properties of the integrated circuit's normal manufacturing method. In some embodiments, only one additional step is added.

Therefore, the manufacturing method of the integrated circuit may include an interconnection stage, wherein a plurality of layers of conductor material are deposited. The layers may be made of aluminium, copper, or their alloys such as AlCu, AlSi, or AlCuSi. The layers may further include a titanium or TiN coating. The conductor layers may be separated from one another by layers of inter metal dielectric (IMD) material. The dielectric material may be silicon dioxide or compounds derived from silicon dioxide. In some embodiments, this structure of interconnection layers serves to connect various electrical or electronic components of the integrated circuit, and to establish the necessary contact points to set up the electrical connections with the outside. The different metal layers may be electrically connected using tungsten vias.

The invention proposes availing of this interconnection stage to include, in the actual structure of interconnection layers, the structure consisting of the layers of conductor material and the layers of dielectric material needed to obtain the MEMS. In embodiments where the integrated circuit needs three or more layers of conductor material for its own use, MEMS may be included in the structure of interconnection layers without requiring additional layers. The structure of interconnection layers may comprise two or more layers of conductor material. In some embodiments, including the MEMS in the structure of interconnection layers may require additional layers of conductor or dielectric material. These additional layers may be applied with the same technology and during the same stage as that for the integrated circuit interconnection layers for own use. This allows for the integrated circuit manufacturing method to be qualitatively unaffected due to inclusion of a MEMS in its structure of interconnection layers.

After the interconnection stage, an attack stage using gaseous HF may remove the dielectric material arranged between the layers of conductor material to form hollow space for the MEMS. HF, particularly dry HF, attacks the dielectric material in a very selective way, whereas the layers of conductor material are hardly attacked. HF surrounds the layers of conductor material to create hollows or cavities or produce loose parts.

In some embodiments, chip manufacturing methods comprise a passivation stage to insulate the integrated circuit from the environment and/or ambience, from an electrical and physical-chemical point of view. The stage comprising an attack with gaseous HF may be performed just after the interconnection stage b) and before the passivation stage. This arrangement may be useful as it reduces the process stages. However, in some embodiments, the passivation stage may be performed just after the interconnection stage b), following the standard manufacturing method sequence. The following passivation stages may be performed between interconnection stage b) and HF attack stage c):

B′) a passivation layer (27) production stage, where passivation layer (27) is arranged on the top layer of conductor material, with passivation layer (27) comprising a bottom layer of silicon dioxide and a top layer of silicon nitride, and

B″) a partial passivation layer (27) removal stage.

The HF reaches the dielectric material through the holes made in the passivation layer during the stage of at least partially removing the passivation layer. The stage of at least partially removing the passivation layer may make accessible points of the conductor material required for external electrical connections (with elements outside the chip). In addition, the stage may provide access to the HF to attack and remove dielectric material for producing, inter alia, hollow space or spaces included in the geometrical structure of the MEMS.

In some embodiments, two partial elimination stages of the passivation layer may be performed: in one stage, the passivation may be removed in those areas where it is desired to establish a connection point between one point of a layer of conductor material and the outside (this stage would correspond to a conventional stage), and in the other stage, the passivation may be removed from those areas where it is desired that the HF attack the dielectric material underneath. This prevents the HF from having access to areas on the chip where its effects are not desirable.

In some embodiments, the stage wherein the passivation is removed from those areas where it is desired that the HF attack the dielectric material underneath takes place before stage c) (the stage comprising an HF attack). The stage in which the passivation is removed from those areas where it is desirable to establish a connection point between one point of a layer of conductor material and the outside takes place after stage c).

In certain embodiments, the HF attack is carried out at HF pressures between 5 Ton and 500 Torr. In some embodiments, the HF attack is carried out at pressures between 10 Ton and 150 Ton. A small amount of water or alcohol vapor may be added as a reaction initiator (catalyst). In embodiments using alcohol vapor as the catalyst, the vapor may not be consumed in the reaction. However, the alcohol vapor serves to initiate the attack, and scavenge water vapor that may be generated during the HF attack. This may help avoid a buildup of reactants due to the water vapor. The silicon oxide attack later may result in the production of a sufficient amount of water to be able to keep the reaction running. The process may not need strict temperature control. In some embodiments, the process may be run at a fixed temperature chosen from the range between 15° C. and 50° C.

In some embodiments, a layer may be a continuous, even layer. In some embodiments, a layer may form a certain pattern on the bottom layer, i.e., a layer that partially covers the bottom layer according to a pre-established pattern. The passivation layer comprises a sub layer of silicon oxide and a sub layer of silicon nitride, where the sub layer of silicon nitride may include some minority components, such as oxygen, hydrogen and others.

In some embodiments, in stage b′) of producing a passivation layer, the layer of silicon nitride is a layer of silicon rich nitride. A layer of silicon nitride rich in silicon is more resistant to attack with HF. A layer of silicon nitride rich in silicon leaves less residue on attack with HF. The Si content may be determined via the refractive index (RI) of the layer of silicon nitride. In some embodiments, the nitride areas rich in silicon may have an RI above 2.2. In some embodiments, the nitride areas rich in silicon may have an RI above 2.3. In embodiments with an RI value equivalent to 2.45, the attack is minimal. This may be achieved, for example, by modifying the SiH₄/NH₃ ratio in a PECVD reactor. Conventionally, the layer of silicon nitride may have a refractive index between 1.9 to 2.1.

In some embodiments, the chip is heated to a temperature of 150° C. before stage c) to remove residues prior to stage c). In some embodiments, the chip is heated after stage c). In some embodiments, the chip is heated after stage c) to a temperature higher than the evaporation temperature of the polymer produced from the reaction between the passivation layer and the HF. The attack with HF may leave some residues on metallic surfaces, which may be complex compounds, possibly polymerized, and derived from ammonium fluoride, for example, (NH₄)₂Si(F₆)₈. The residues may be removed by heating the chip above a certain temperature. In some embodiments, a temperature of 110° C. may be used. In some embodiments, a temperature of 170° C. may be used. In some embodiments, a temperature of 180° C. may be used. In embodiments where a temperature of 250° C. is used, the residue may be removed completely.

In some embodiments, the product of the reaction between the passivation layer and the HF, which is at least partially deposited on the metallic surfaces as a residue, may not be a polymer. The residue may be removed by heating the chip to a temperature higher than the evaporation temperature of the residue. The amount of residue after HF attack may be minimized by using a layer of silicon nitride rich in silicon.

In one embodiment, after stage c) an ALD (Atomic Layer Deposition) coating stage is carried out. The ALD coating technique is known in the art and an application thereof is described, for example, in issued U.S. Pat. No. 7,426,067. The ALD coating allows for covering the surfaces of conductor material with materials (for example, other metals) that have particularly interesting properties. In some embodiments, thin (for example, monoatomic), even layers may be deposited. In some embodiments, monoatomic layers may be deposited several times to form a thicker layer. For example, a pulsed process may be used, and a monoatomic layer may be deposited at each pulse. Repeating the process over multiple pulses may allow for the formation of a thicker layer. This way, various improvements may be achieved.

The materials used in the structure of interconnection layers (dielectric material and conductor material) may be selected for optimum result for a conventional integrated circuit. However, MEMS structures may require properties for which these materials are not particularly suitable. For example, hardening properties may be improved by adding a very hard metallic layer on top of the layers of conductor material. The hard metallic layer may be composed of Ru, Pt or ZnO, or alloys thereof. Properties may also be improved to reduce stiction problems.

The layer of conductor material may be coated even when residues from the reaction between the passivation layer and the HF remain on the layer. The ALD coating may recoat the layer of conductor material and the residue arranged thereon, to obtain a new conductor surface (if the ALD coating is conductive) that is very coarse. This coarse surface may be exhibit improved properties that reduce stiction problems.

In order to prevent the ALD coating, when it is deposited on all surfaces (both metallic and dielectric), from causing unwanted short circuits, the ALD coating may be made in a time shorter than the percolation time. When the ALD coating begins, the whole treated surface may not be recoated instantly. Instead “islands”, “bumps”, or formation cores may develop, which broaden during the reaction time until they interconnect together, finally, to the point that they completely recoat the target surface. The time required for the complete coating is the percolation time. If the reaction is interrupted before said percolation time, i.e., before the surface to be treated is totally recoated, a partially recoated surface may be obtained with the said “islands” or “bumps”. These “islands” or “bumps” are suitable as electrical contacts, and no short circuit is caused with other elements on the MEMS device because the “islands” are not interconnected.

In embodiments where the MEMS has a mobile element, the mobile element may be subject to movement during the ALD coating stage. The mobile element may be loose and physically independent. The mobile element released during the HF attack stage c) may be in contact with and supported by the layer underneath it. This makes correctly recoating the bottom surface of the mobile element and the top surface of the layer under the MEMS difficult. Moving the mobile element allows the reagents from the ALD method to reach these surfaces perfectly and the ALD coating to be performed uniformly on all the desired surfaces. In some embodiments, a Self Assembled Monolayer (SAM) coating stage may follow the ALD coating stage. In some embodiments, a SAM coating may be performed instead of the ALD coating.

The SAM coating may helpful in reducing stiction.

In some embodiments, and/or, a stage of producing a new passivation layer be carried out (which may be equivalent or different to stage b′)) after the attack stage c). This stage serves to physically close the chip and insulate and protect it from the environment. In some embodiments, this stage may be carried out after the ALD coating stage.

The HF may attack the dielectric material in all directions. This makes possible the creation of cavities, or release mobile elements that are completely loose (deposited on the layer underneath them). An area of the chip that need not be attacked may be protected by covering the area with a layer of conductor material. A layer of dielectric material, underneath a layer of conductor material, may be attacked via a plurality of holes included in the layer of conductor material that are sized such that they allow HF molecules to pass through. However, these holes are small enough that to not allow nitrides to pass through.

In some embodiments, these holes may have a diameter less than or equivalent to 500 nm. In some embodiments, these holes may have a diameter less than or equivalent to 100 nm. Before the stage of producing a new sealing layer takes place, the layer of conductor material with the holes (in some embodiments, the top layer) may undergo an ALD coating. The ALD coating may close the holes which contributes to depositing the new sealing layer satisfactorily, covering all the holes. In some embodiments, the holes have a circular cross section. In some embodiments, the holes may not have a circular cross section. These holes may have a cross section with an area that is smaller or equivalent to the area of a circle with the indicated diameter.

In some embodiments, a layer resistant to HF attack may be added underneath the bottom layer of conductor material. This layer protects the structure of layers forming the electrical or electronic elements from the HF. The interconnection structure may comprise several layers of conductor material (more than two), and some of them (one of the bottom ones) may be used to include a layer of conductor material arranged underneath the MEMS devices. This layer acts as a protection barrier to prevent the HF from reaching the structure of layers forming the electrical or electronic elements. For example, HF may be prevented from reaching the Inter Level Dielectric (ILD) layer, since the ILD layer is attacked quickly by the HF and may produce waste products.

In some embodiments, HF may be prevented from attacking these layers by depositing a very fine layer of amorphous silicon on top of the layers that need protection. In some embodiments, the very fine layer of amorphous silicon is a few nanometers thick.

In some embodiments, a partition of HF resistant material may be added around the MEMS. This partition may extend perpendicular to the substrate and surround the MEMS in a direction parallel to the substrate. The MEMS is surrounded by a partition so that the HF may not spread uncontrollably parallel to the substrate. This may allow determination of the maximum extent of the HF attack, parallel to the substrate. The term “HF resistant material” may be defined as any material that is resistant to gaseous HF, where said gaseous HF is dry. The “dry” HF does not include water or alcohol, although there may be water from the actual HF reaction.

In some embodiments, the HF attack may start with the addition of a certain amount of water or alcohol vapor, which acts as a catalyst for starting the reaction. The rest of the attack may be performed “dry”, whereby no further water or alcohol is added. The reaction generates a certain amount of water enough to maintain the reaction, i.e., it is a self-maintained reaction. In some embodiments, the reaction is controlled (by pressure, temperature control, and the presence of alcohol vapor) to prevent production of an excessive amount of water. Excess water may cause an excessively energetic and uncontrolled attack. The definition of the term “HF resistant material” also includes those materials which are minimally attacked compared to the dielectric material. For example, aluminium and copper are “HF resistant materials”.

In some embodiments, the partition made of HF resistant material may be based on elongated rods of tungsten, similar to rods made conventionally to interconnect different layers of conductor material.

In some embodiments, at least one direct interconnection is established between the substrate and at least one of said metallic layers by means of an HF resistant material. A direct connection anchors the layer of conductor material to the substrate, preventing the structure from collapsing in the event that the HF removes all the dielectric material arranged on top of the layer of conductor material.

In some embodiments, the interconnection material may be a metal. Such embodiments pose a risk of establishing non-desired electrical contacts when interconnecting the layers of conductor material with the substrate (which is also a conductor). A layer of amorphous silicon, which is an insulator, may be inserted between the interconnection and the substrate to mitigate the risk.

In some embodiments, a plurality of layers of conductor material may be deposited in the interconnection stage. In some embodiments, a maximum of six layers of conductor material may be deposited in the interconnection stage. In some embodiments, MEMS devices may require five layers (or less) of conductor material. In some embodiments, MEMS devices may only require three layers of conductor material. In embodiments where the interconnection stage is limited as indicated, the MEMS may be completely integrated in the actual structure of interconnection layers of the integrated circuit, whereby the conventional manufacturing method of the integrated circuit is virtually unaffected.

As already mentioned, the passivation layer usually comprises a sublayer of silicon oxide and a sublayer of silicon nitride. When this passivation layer is attacked, first the silicon nitride is attacked, but once this sublayer is perforated (for example, through the use of patterning), the attack extends to the sublayer of silicon oxide. The sublayer of silicon oxide is attacked more easily than the sublayer of silicon nitride, so that the sublayer of silicon nitride remains in a cantilever arrangement around the attack holes. These cantilever areas are fragile and prone to breaking. To avoid this situation, the two sublayers of the passivation layer may be made with masks that are different to one another. The sublayer of nitride may have some areas where it extends passing completely through the sublayer of oxide, and reaching the layer lying underneath (in some embodiments, a layer of conductor material). If the attack takes place in one of these areas, the hole may be made to form a chimney that passes through the sublayer of nitride without the HF coming into contact with the oxide.

A further aim of the invention is a chip of the type indicated at the beginning characterized in that it comprises, in addition, at least one MEMS arranged in said structure of interconnection layers, where said MEMS comprises at least one hollow space, where at least one part of the hollow space is arranged under a sheet of conductor material belonging to one of the layers of conductor material. “Under” means in the direction towards the substrate. In other words, it is not possible to directly (in a straight line) access the hollow space from the outside (through an opening made in the passivation layer) as the sheet of conductor material is in the way. Therefore, it is not possible to create the hollow space using techniques that attack the dielectric material and are directional, such as for example the techniques that use plasma.

In some embodiments, in addition the chip comprises a passivation layer, where passivation layer is arranged on top of the top layer of conductor material, with passivation layer comprising a bottom layer of silicon dioxide and a top layer of silicon nitride. These layer structures may be superimposed or at least partially superimposed and, may be continuous or homogenous layers. In some embodiments, the layers may form a certain design on the bottom layer, made up of masks.

A MEMS structure like the one described above may be obtained when a sheet of conductor material belonging to one of the layers of conductor material has at least one part of its lower surface (facing the substrate) free of dielectric material. The chip may include any of the characteristics derived from the method according to the invention.

In some embodiments, the MEMS included in the integrated circuit comprises a conductor element as a loose part. Processes and materials (fore example, metals) normally used to manufacture integrated circuits usually suffer from the drawback that they accumulate residual stresses and stress gradients. This drawback may be irrelevant for a conventional integrated circuit. However, in a MEMS, if a cantilever metallic sheet has these accumulations of residual stresses and/or stress gradients, it may become deformed. This deformation may be such that it renders the MEMS useless or, at least, prevents it from working properly. However, if the MEMS operates via parts that are completely loose, it may be easier to compensate or neutralizes the effects caused by said states of stress. Also, while the MEMS is working, temperatures may be high enough to influence the mechanical properties of the metallic sheets forming part of the MEMS. For example, if the metallic sheets are made from aluminium (or one of its alloys), there may be fluency problems with the cantilever sheets. This problem may also be resolved more easily if the MEMS operates via parts that are completely loose.

The MEMS may also include at least two capacitor plates that can generate electrostatic fields over the loose part that are capable of moving said loose part. Document WO 2004/046807 describes a series of these devices, for example on pages 3 to 17 and 19 to 27. Document WO 2004/046807 also describes a series of these devices, as well as documents WO 2005/101442, WO 2005/111759 and WO 2005/112190.

It is particularly advantageous that the MEMS also comprises at least two contact points in an electrical circuit, where the loose part is able to adopt a position wherein it is simultaneously in contact with both contact points, so that an electrical connection can be established between the contact points, whereby the MEMS acts as a relay, particularly like the relays described in document WO 2004/046807, on pages 3 to 12 and 19 to 26.

In some embodiments, the integrated circuit of the chip comprises a MEMS device from the group of MEMS devices made up of electrical relays, accelerometers, inclinometers, Coriolis force detectors, pressure sensors, microphones, flow rate sensors, temperature sensors, gas sensors, magnetic field sensors, electro-optical devices (particularly the digital, reflector electro-optical devices known as DMD—Digital Micromirror Device), optical switching matrices, image projector devices, analogue connection matrices, electromagnetic signal emission and/or reception devices, power supplies, DC/DC converters, AC/DC converters, DC/AC converters, A/D converters, D/A converters, and power amplifiers.

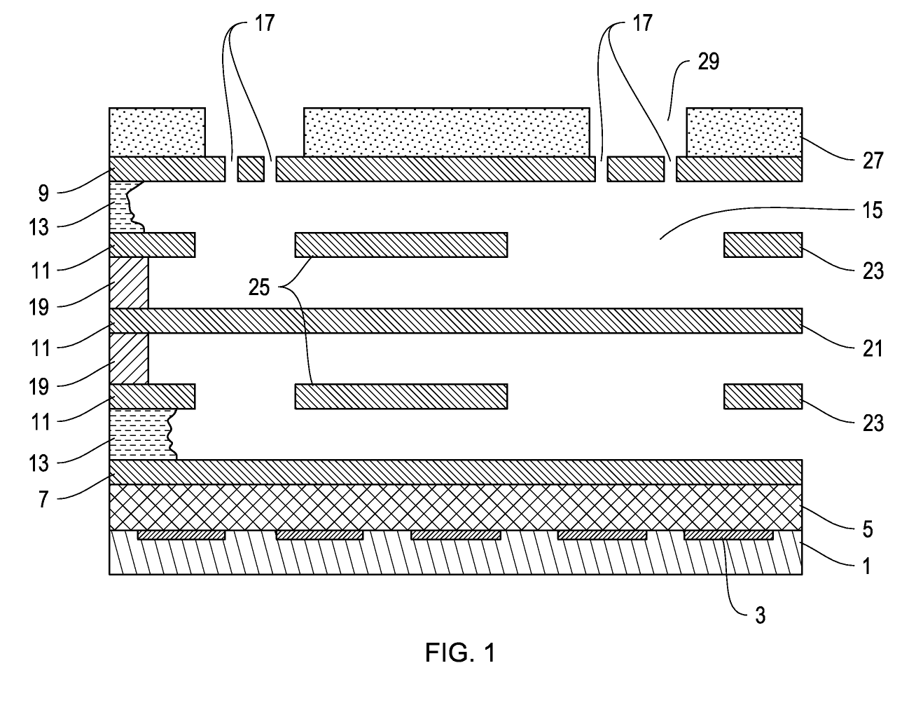

FIG. 1 shows a diagrammatical view of a cross section of a chip according to the invention. The thickness of the layers has been magnified. The cross section shows a MEMS that forms a relay with a cantilever electrode 21, two contact electrodes 23 and two action electrodes 25.

The chip comprises a substrate 1 on which there is a plurality of electronic elements 3, for example transistors. Next there is a layer of borophosphosilicate glass (BPSG). This layer, called the Inter Level Dielectric (ILD) layer, may consist of a layer of doped oxide (for example, BPSG or phosphosilicate glass (PSG)) and a layer on top of non-dopated oxide. The structure of interconnection layers starts on top of the layer of borophosphosilicate glass 5, with one bottom layer of conductor material 7 and one top layer of conductor material 9. Between the bottom layer and the top layer of conductor material 7 and 9, there are three additional layers of conductor material 11 separated from one another by layers of dielectric material 13. The dielectric material has mostly been removed to form the cavity or hollow space 15 which allows the cantilever movement of the electrode 21. FIG. 1 shows, diagrammatically and as an example, the end of two areas of the dielectric material attacked by the HF.

The top layer of conductor material 9 has some holes 17 through which the HF that has attacked the dielectric material may pass. In the case of the cantilever electrode 21 holes have not been included because the HF may skirt around the cantilever electrode 21 so that it may attack the dielectric material lying underneath the said cantilever electrode 21 without the need for said holes. In fact, since the cantilever electrode 21 is relatively narrow (perpendicular to the paper), the HF may skirt around it in the direction of its width.

In the left of FIG. 1 two paths 19 of electrical connection may be seen between layers of conductor material.

In the example in FIG. 1, the MEMS structure starts immediately from the bottom layer of conductor material 7. However, in some embodiments, there may be some additional layers of conductor material between the MEMS and the layer of borophosphosilicate glass 5 to establish a certain electrical connection between the electronic elements 3 provided underneath the MEMS.

The chip is initially closed by a passivation layer 27. During the stage of partially removing passivation layer 27 openings 29 are formed, through which the HF may attack the dielectric material. After attacking with HF, a new passivation layer may be produced that closes openings 29. In some embodiments, a new sealing (for example, Wafer Level Chip Scale Packaging (WLCSP)) may be produced to close openings 29. As the size of holes 17 is small enough, the new sealing layer does not pass through said holes 17. In some embodiments, the removal of the passivation layer 27 is partial or not complete.

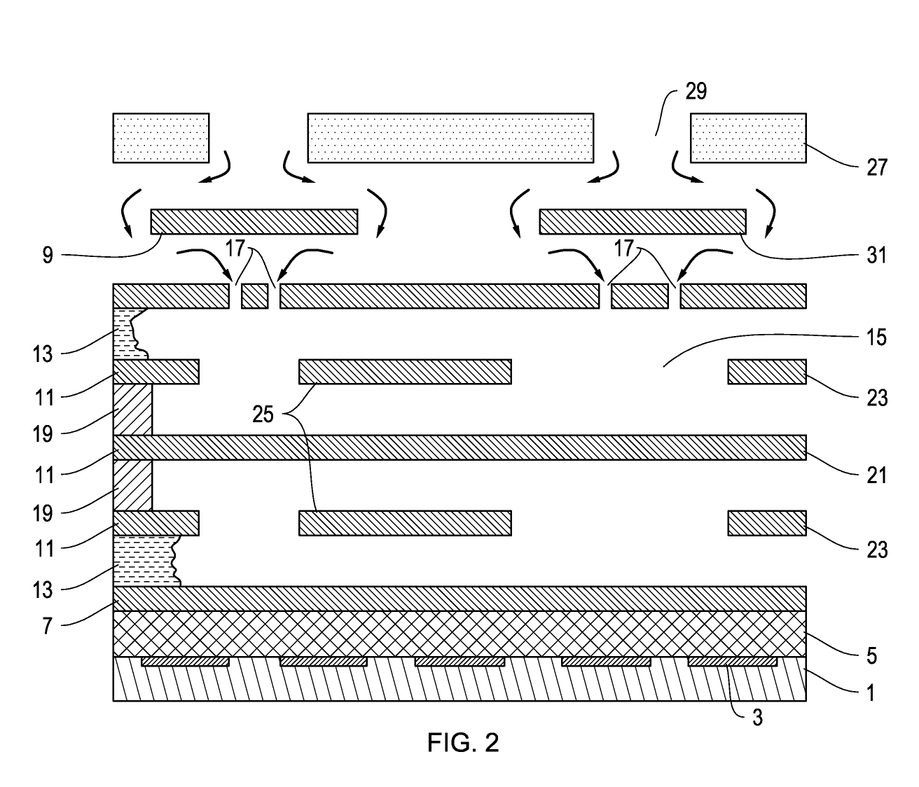

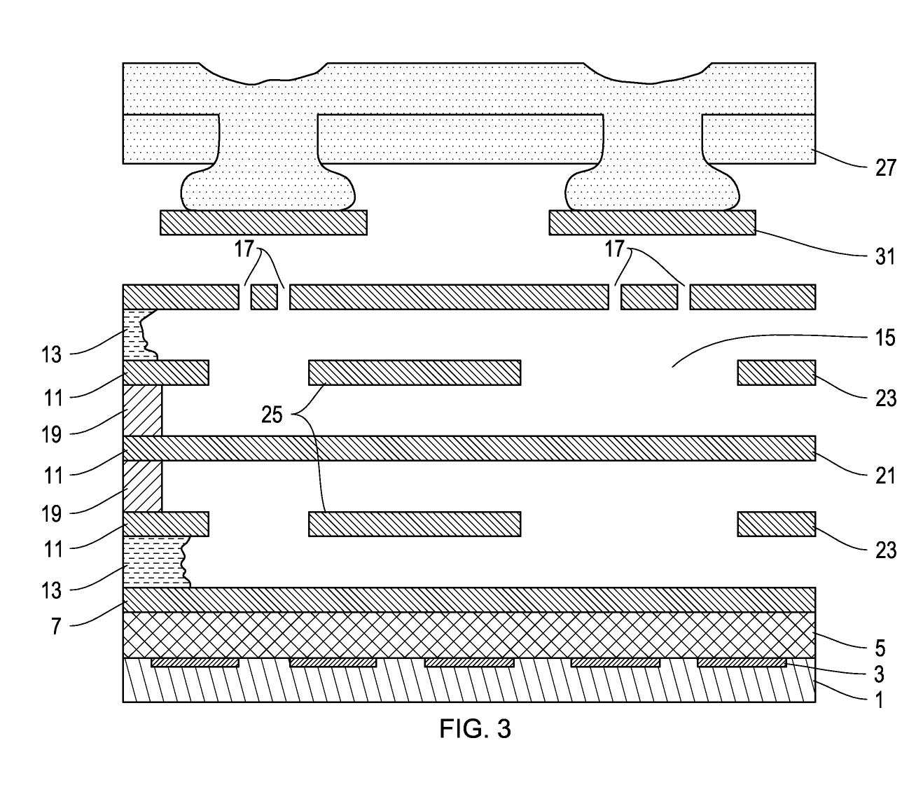

FIGS. 2 and 3 show another embodiment of the invention. In this case, the partial removal of stage b′) produces openings 29 that are arranged over plates of conductor material 31 belonging to the top layer of conductor material 9. Plates 31 do not prevent the HF attack. The HF may move around them, as shown diagrammatically in FIG. 2 by the arrows. However, plates 31 may be useful during the stage of producing a new sealing layer, because the new sealing layer passes through opening 29 and is deposited on plate 31 until it fills, at least partially, the hollow space between each opening 29 and its corresponding plate 31 (see FIG. 3). Therefore the arrangement of these plates 31 facing openings 29 facilitates the subsequent stage of producing a new sealing layer. Including said plates 31 is independent of using holes 17. In some embodiments, only plates 31 may be used, omitting the layer of conductor material that includes holes 17.

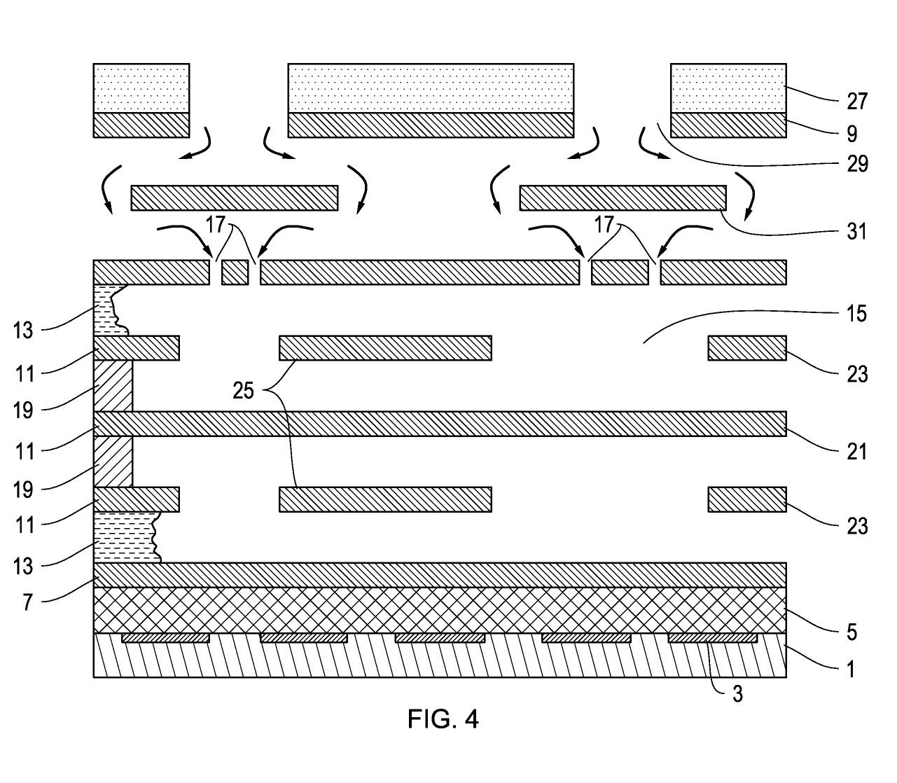

FIG. 4 shows another embodiment of the invention, similar to that in FIGS. 2 and 3. In this embodiment, passivation layer 27 rests directly on the top layer of conductor material 9, and plates 31 belong to an intermediate layer of conductor material. In effect, inserting a layer of dielectric material between the top layer of conductor material 9 and passivation layer 27 represents an additional stage of the conventional CMOS procedure, and it may be beneficial to remove it. However, generating a new sealing layer would take place as shown in FIG. 3.

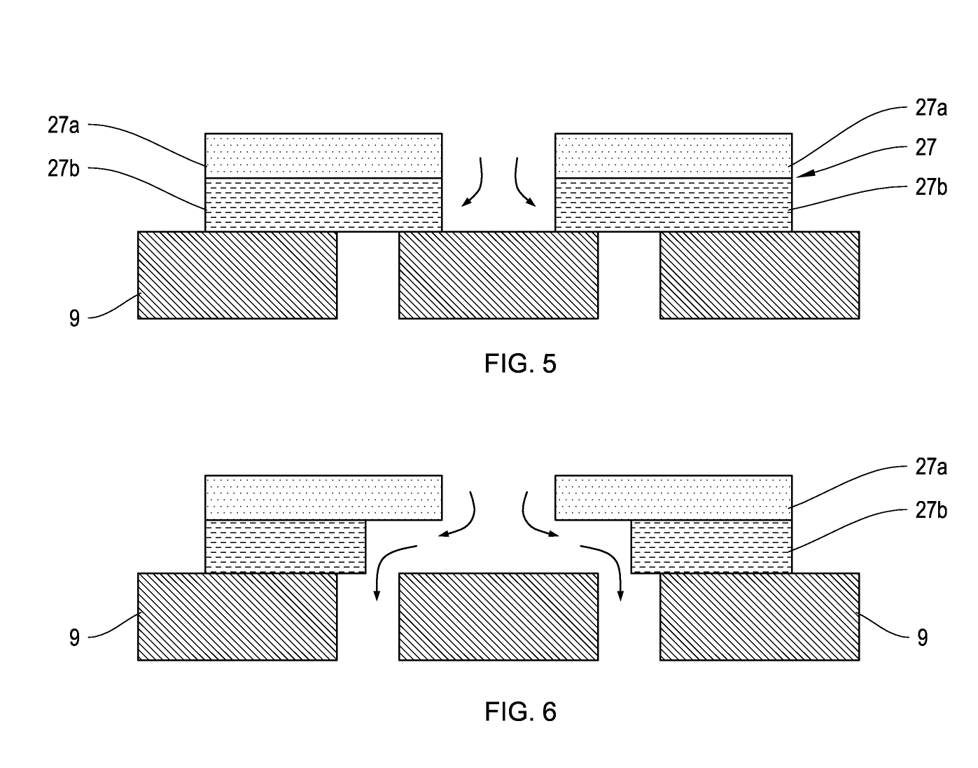

FIGS. 5 and 6 show another embodiment of the invention. In this embodiment, passivation layer 27 comprises a sublayer of silicon nitride 27a and a sublayer of silicon oxide 27b, and the sublayer of silicon oxide 27b is attacked by the HF. This allows the HF access to the layers of dielectric material, although the removal of the passivation layer has taken place in an area under which there is conductor material instead of dielectric material.

In some embodiments, the part of said top layer of conductor material (9) arranged on said MEMS has a plurality of holes, and the following layer of conductor material arranged under said top layer of conductor material (9) also has a plurality of holes that are not aligned with the holes in said top layer of conductor material. This allows said gaseous HF to run in zig-zag fashion in order to be able to reach the area of said MEMS. As a result, the subsequent sealing of the integrated circuit may be performed more easily, for example, by depositing another metallic layer (for example, Al), and/or depositing another passivation layer and/or WLCSP packaging.

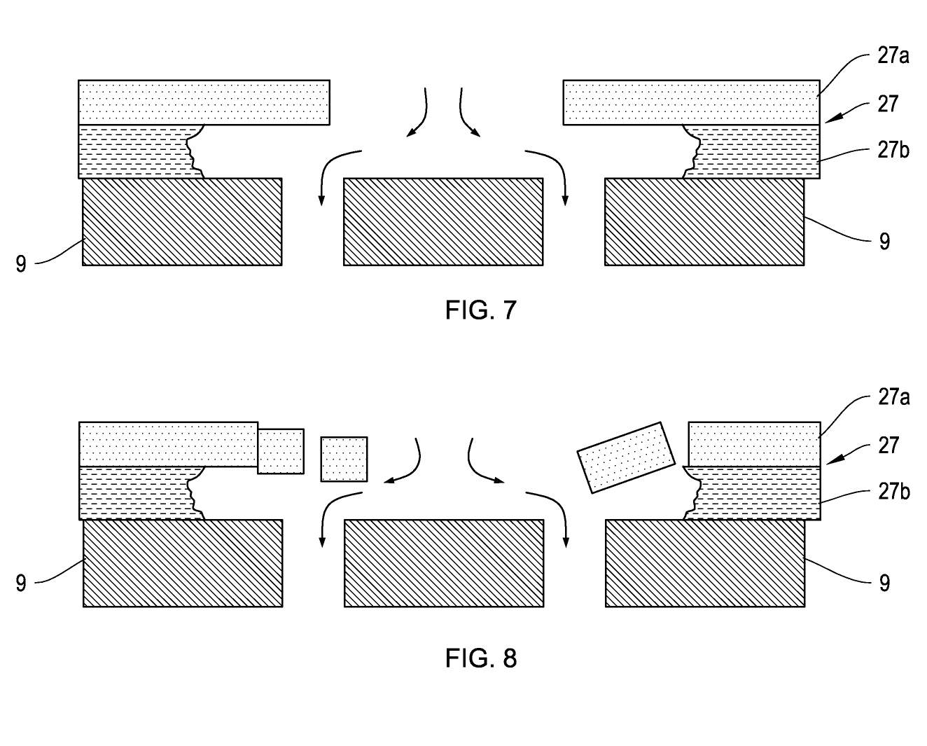

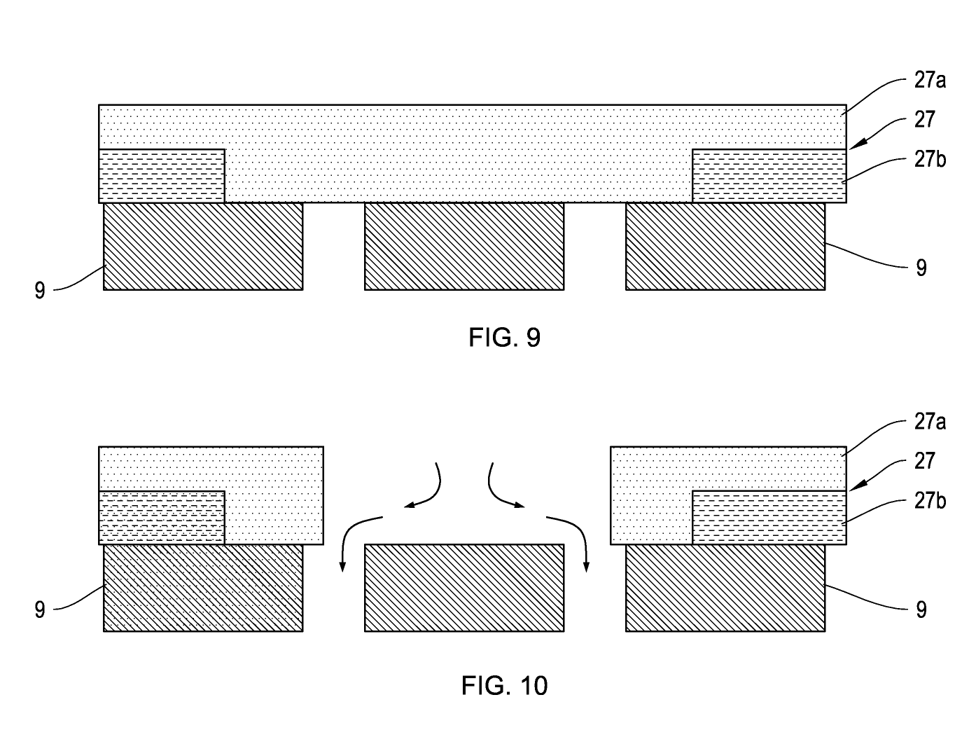

FIG. 7 shows, schematically, how the HF attacks the sublayer of silicon oxide 27b in a more pronounced way than the sublayer of silicon nitride 27a. This may cause a cantilever that can bend and/or break in an uncontrolled way (FIG. 8). To avoid this, the passivation layer may be made with two different masks, such that in some areas the silicon nitride sublayer 27a extends as far as the bottom layers (of conductor material 9 and/or dielectric material 13), as shown in FIG. 9. When the HF attacks passivation layer 27 in these areas, a “chimney” is formed that is completely wrapped in silicon nitride, whereby the HF does not come into direct contact with the silicon oxide (FIG. 10). In these embodiments, the silicon nitride sublayer 27a (which is approximately 300 nm) may be thicker than usual. The thickness may vary by CMOS process. In some embodiments, the silicon nitride sublayer 27a may be of a thickness between 500 nm and 700 nm. In some embodiments, the passivation may be planarized (e.g. with Chemical Mechanical Polishing (CMP)) to avoid cracks during and after the etching.

While the foregoing describes one or more MEMS devices arranged using one more an integrated circuit fabrication techniques that may be employed for various types of applications, the applications discussed below should not be considered as limited to this type of process. The foregoing is one type of process to implement the applications given below.

### Layer Stack, O-shaped Springs, and FreePlate

A very thin CMOS layer (typically less than 1 μm thick in CMOS backend processes) may have a large curvature after being released. Large curvatures may manifest on released metal layers due to lack of optimization for flat structures in the CMOS process. The curvatures may increase with lower nodes (newer processes), due to further thinning of metal layers. In some embodiments, the mean and the deviation of the curvature are high. Though a large mean curvature may be accounted for, a large deviation may cause poor repeatability and make the building process difficult. It may not be economically viable to change the curvature and sufficiently improve repeatability by process adjustments in applications where the process needs to be as standard as possible. Additionally, very thin layers may be soft and easily deformed. This may be problem in embodiments where a rigid MEMS structure is desired. Such a MEMS structure built from soft thin layers may deform when subjected to forces higher than the MEMS layers can withstand. In embodiments where a large MEMS structure is desired, such a structure may cause failure of the MEMS device due to a large curvature.

In one aspect, a chip comprising a MEMS arranged in an integrated circuit comprises metal layers less prone to curvature. In some embodiments, thin metal layers are stacked together, and joined by a dense array of vias, to form an equivalent thicker metal layer. Such a structure may help reduce mean and deviation of bending due to residual and gradient stress, and offer improved repeatability. The curvature may be reduced because the inertia modulus of the section may increase while the stress gradient on each individual metal layer remains the same. The repeatability of many parameters may be reduced because, among other things, the inherent variability of the metal layers may be canceled out by averaging. In some embodiments, a large number of stacked layers lowers the deviation and mean of curvature. In embodiments with different types of curvature in the metal layers, a small number of metal layers may be preferred. For example, if one metal layer is concave, while the other is convex, stacking only two layers may lower overall curvature compared to stacking three layers. In some embodiments, stacking of metal layers to form an equivalent thicker layer may offer improved stiffness. The bending stiffness is increased because the thickness is increased. The axial stiffness is increased because the section is increased. Large forces may be applied to the equivalent thicker layer without causing curvature. The equivalent thicker layer may remain rigid even if moved or tilted.

In some embodiments, soft springs may be used to increase the flatness (i.e., reduce the bending) despite the large curvature. Temperature variation may induce thermal stresses and thermal expansions/contractions, which may be transmitted to the springs of the MEMS structure. This in turn may not allow for very long MEMS springs (desired for lower K constant) since the tip vertical displacement would be high and not repeatable. Soft springs may not bend much despite their length. The topology of a soft spring may allow expansion/compression of the structure attached to the spring, without significant bending of the spring itself.

In some embodiments, the MEMS structure comprises a part that is detached from the structure and is mechanically free. Such a part may not be affected by residual stress, and may obviate the need for soft springs. Additionally, such a part may not be affected by creep. This may be useful in embodiments of MEMS devices built with aluminium, since aluminium is susceptible to large creep due to its low melting temperature.

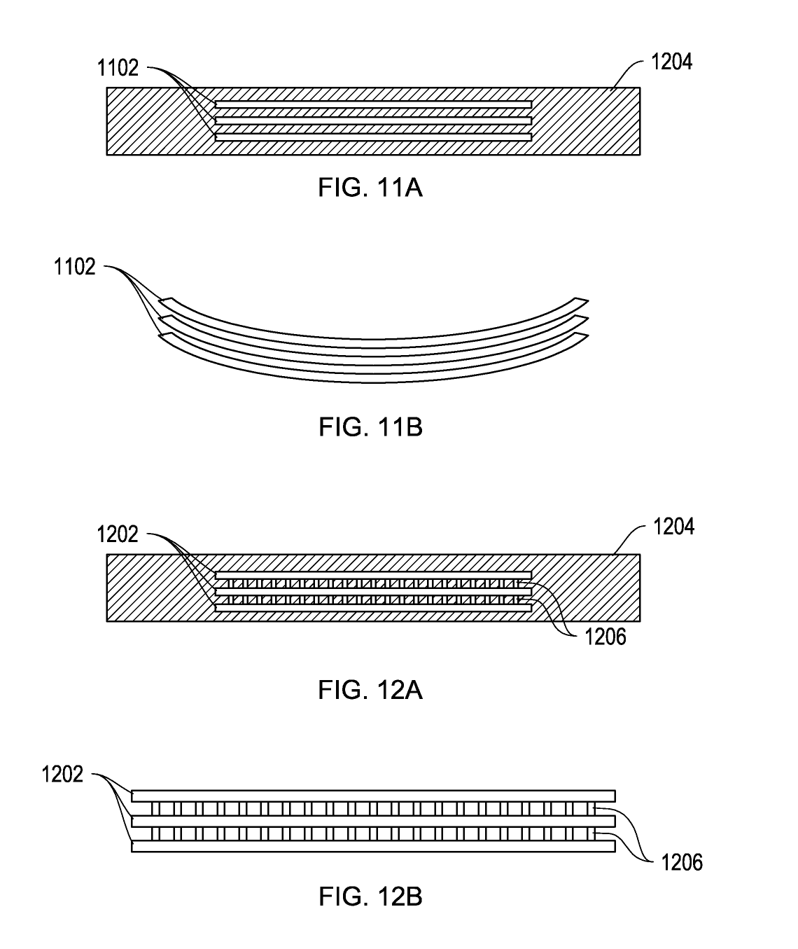

FIG. 11 shows illustrative embodiments of a structure with three thin metal layers, without stacking Metal layers 1102 in FIG. 11A are released from oxide 1104. However, metal layers 1102 bend due to stress after release, as shown in FIG. 11B.

FIG. 12 shows illustrative embodiments of a structure with three thin metal layers stacked together, and joined by a dense array of vias. Metal layers 1202 in FIG. 12A are released from oxide 1204. After release, the thicker equivalent layer produced from layers 1202 and vias 1206 is resistant to curvature and/or deformation, as shown in FIG. 12B. Thus, an arrangement of vias may reduce unwanted deformations, enabling a more repeatable and predicable manufacturing process. Such an arrangement of vias may enable a more robust MEMS component such as a switch because the relationship between contacting elements is now more predictable and reliable.

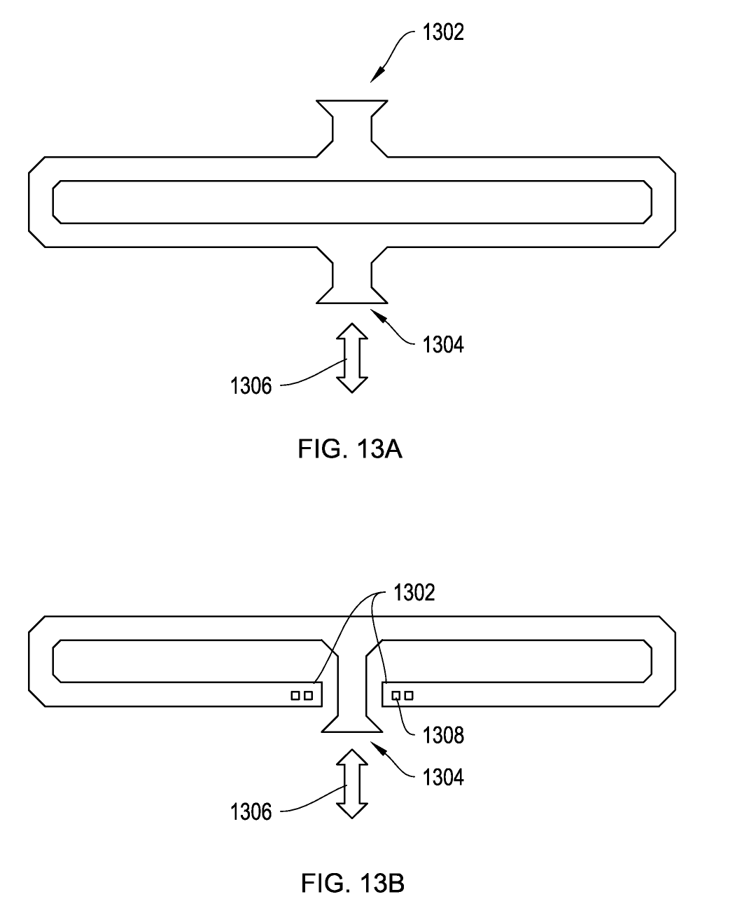

FIGS. 13A and 13B shows top views of illustrative embodiments of o-shaped springs that reduce bending in metal layers, despite large curvature. The springs are robust against curvature because their end and beginning are close to each other, which partially cancels out the z offset of the curvature. They are more repeatable than a single arm spring since final curvature is the average curvature of two arms. In FIG. 13A, the MEMS structure connects to end 1304 of each spring. The springs are compliant in the direction pointed out by arrow 1306. Expansion or contraction of the MEMS structure attached to the spring may take place in this direction. In FIG. 13B, anchors 1302 are connected with vias 1308 to other metal levels. The anchoring point is where the spring is attached to the substrate or other metal layers ultimately fixed to the substrate. The initial and final point of the spring are very close in this design.

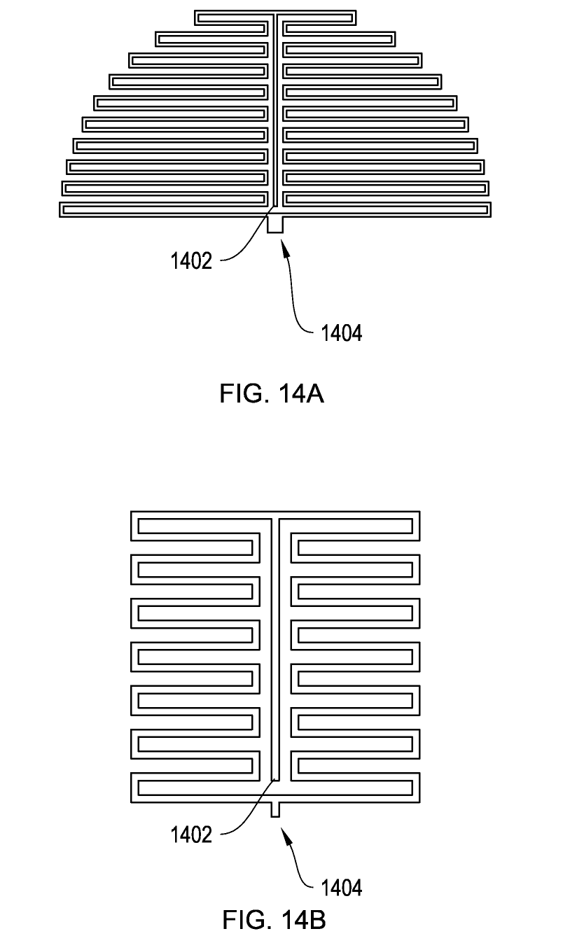

FIG. 14 shows top views of illustrative embodiments of springs with multiple meanders. The MEMS device connects to end 1404, while fixed point 1402 acts as anchors, as shown in FIGS. 14A and 14B. The anchoring may be implemented with vias. The semicircular shape of the spring in FIG. 14A minimizes maximum displacement of the spring while minimizing the stiffness. The vertical displacement of the MEMS connection point is extremely low compared to the maximum vertical displacement. The spring may be composed of a single or multiple metal layers. In order to achieve the softest spring, the number of layers will be determined by the curvature of those layers and their stiffness. For example, three stacked metal layers can be much stiffer can one metal layer, but a spring of three stacked metal layers may be much larger than a single metal layer spring as the curvature of the first one is much lower as well. The metal layers are joined with vias.

### Change of Resistance on a Metal Line by Overpassing the Electromigration Limit

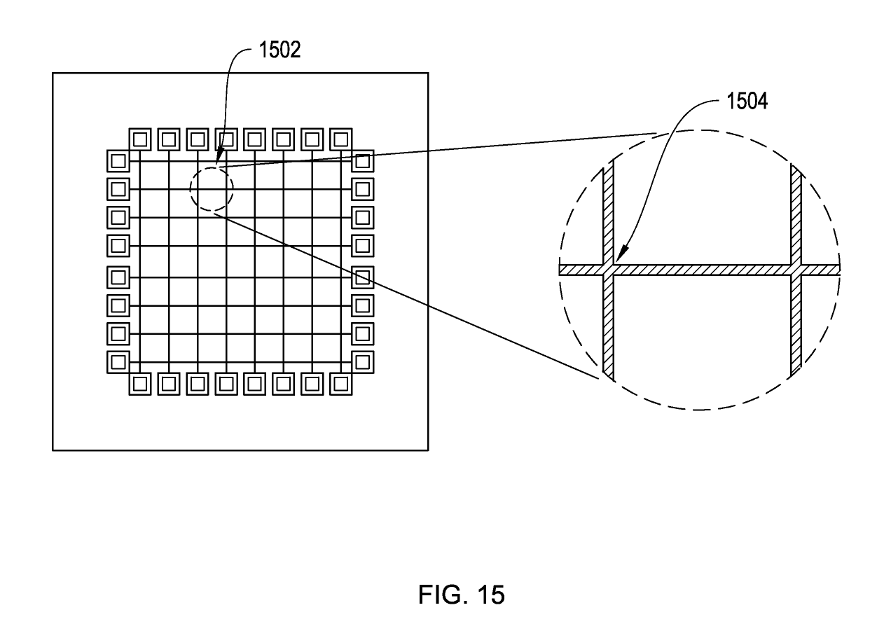

In one aspect, a chip comprises a multi-level memory MEMS device arranged in an integrated circuit. Overpassing the electromigration limit, applied for a limited amount of time, may lead to a local multi-level memory with high density, low power consumption, and high speed, with limited re-programmability. The local multi-level memory may provide additional advantages including low cost, use of a standard CMOS process, and high density. The resulting memory density may be larger than current state-of-the art Flash memories. The re-programmability of the memory may be comparable to existing Flash devices, given enough resolution and dynamic range in the resistance values. In some embodiments, the same effect may be used for thermal switches, or to trim resistors. In some embodiments, removal of the oxide (IMD) around the resistor/metal line allows this effect to be achieved with reduced power consumption and higher speed. FIG. 15 shows an embodiment of a 64-node multi-level memory, where cell 1502 is programmed by changing the resistance value of tungsten via 1504. Bits stored in a via may correspond to the lower significant bits of its resistance value.

### Continuous Vias

In some embodiments, a partition of HF resistant material may be added around the MEMS of a chip comprising a MEMS arranged in an integrated circuit. This partition may extend perpendicular to the substrate and surround the MEMS in a direction parallel to the substrate. The MEMS is surrounded by a partition so that the HF may not spread uncontrollably parallel to the substrate. This may allow determination of the maximum extent of the HF attack, parallel to the substrate. The term “HF resistant material” may be defined as any material that is resistant to gaseous HF, where said gaseous HF is dry. The “dry” HF does not include water, although there may be water from the actual HF reaction.

In some embodiments, horizontal and vertical continuous vias may be used as partitions of HF resistant material around the MEMS to control the spread of HF in to the substrate. The HF resistant partition may be made of elongated rods of tungsten, similar to rods made conventionally to interconnect different layers of a semiconductor. The tungsten rods may limit the gaseous HF from spreading laterally from the location of the MEMS device.

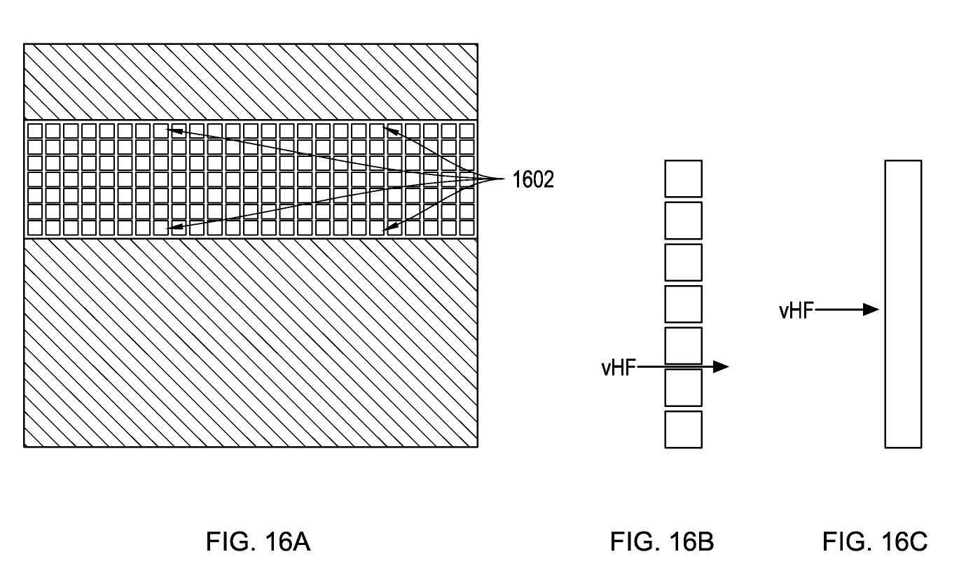

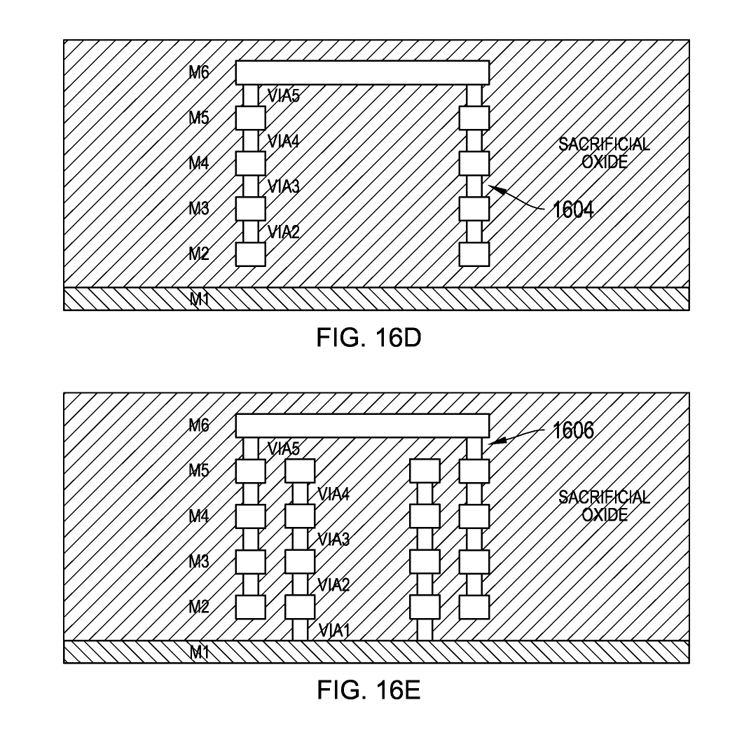

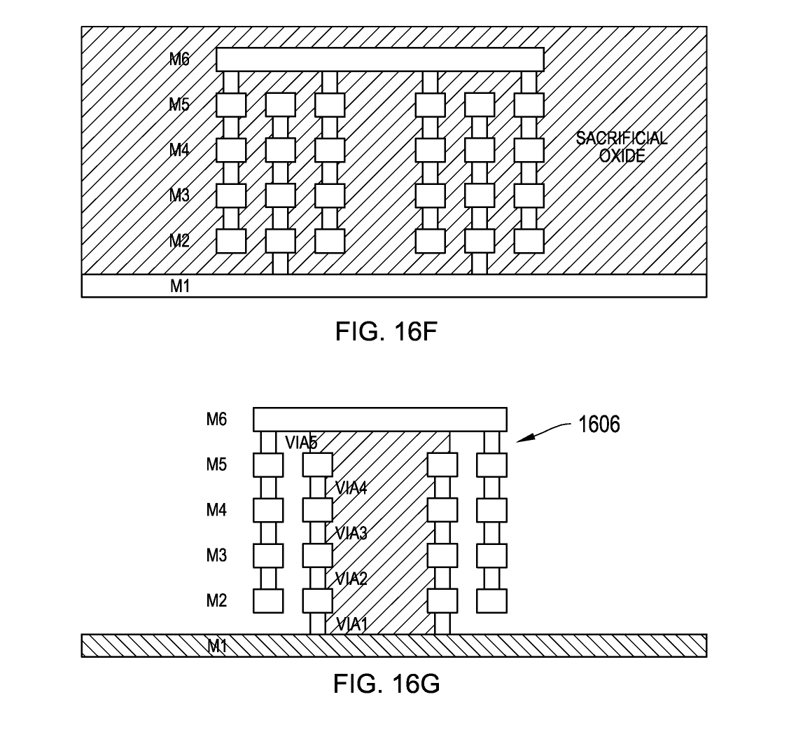

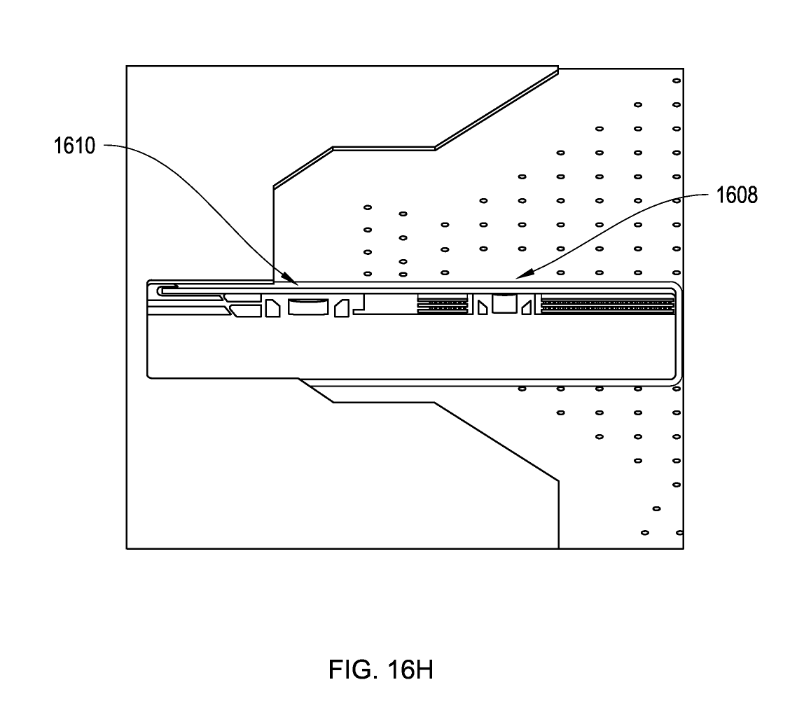

In the embodiment shown in FIG. 16, vertical continuous vias 1602 make tungsten-tungsten contacts. These vias may be stacked vertically beyond the edge of the metal. Stacking vertically may make the device more robust in front of vertical curvature induced by the release process. Tungsten-tungsten contacts are harder and resistant to the native oxide, and may offer improved reliability. One problem with typical chip fabrication foundries (e.g., Tier 1 foundries) is that vias are typically formed as a stack of multiple vias where each section may be associated with a layer of the integrated circuit (See FIG. 16B). In this configuration, there may be gaps between sections of the vias stack that allow vapor HF to pass through, resulting in excessive etching and possibly, a run away process. The applicant realized that a continuous vias extending vertically across multiple integrated circuit layers (See FIG. 16C) will not have gaps and, therefore, not allow vapor HF to pass through, preventing excessive etching. In some embodiments, the continuous vias may be implemented as columns with anchors on the chip. The continuous vias may be implemented to have low parasitic capacitance. Typically, existing foundries consider this a design rule violation (DRV). The applicant is the first to realize the advantageous effect of using a continuous vias, in contrast to the accepted standard, so that a CMOS MEMS device may be manufactured in a repeatable and cost-effective manner. Thus, a continuous vias enable more predictable control of the rate of etching with or without other techniques such as time and/or pressure control.

FIGS. 16D-16F show embodiments of one-, two-, and three-wall schemes for implementing a continuous via, respectively. Vias 1604 in FIG. 16D comprise a ring of continuous vias (VIA2-VIA5) in the form of a closed loop. Continuous vias may avoid release of device anchors due to excessive etching time, offering more robustness. Continuous vias may also enable the mechanical attachment of two different metal layers, while keeping them electrically isolated. In some embodiments, any number of walls (n-wall scheme) may be used to implement a continuous via arrangement. For example, FIG. 16E shows a cross-section of a two-wall scheme for a continuous via, and FIG. 16F shows a cross-section of a three-wall scheme for a continuous via arrangement. In some embodiments, other combinations of metals and vias may be used with the same topological shape of the n-wall scheme for continuous vias.

While FIG. 16E shows the two-wall scheme continuous via 1606 prior to etching, FIG. 16G shows the same two-wall scheme continuous via 1606 after etching with vaporized HF. The etching may be performed in a plurality of steps. Each step may etch away part of the sacrificial oxide, subsequently leaving behind the structure shown in FIG. 16G. The structure may be advantageous since the capacitance between the two electrodes may be minimized due to less oxide between the walls. Less oxide reduces capacitance since oxide has a higher permittivity than vacuum. In some embodiments, etching may be performed for a time longer than necessary, i.e., more etching steps. This may result in the top metal M6 (FIG. 16G) being fully released and rendering the structure non-functional. FIG. 16H shows a Scanning Electron Microscope (SEM) image after release of continuous vias 1608 and 1610. Continuous via 1608 is implemented with a two-wall scheme, with a column between the top metal layer M6 and metal layer M1 (FIG. 16G). The column attaches the metals mechanically while keeping them electrically isolated. Continuous via 1608 illustrates a spring anchor with continuous via.

### Al Sputtering

In some embodiments, a chip comprising a MEMS arranged in an integrated circuit may comprise a top layer of conductor material arranged on the MEMS that has a plurality of holes, and a following layer of conductor material arranged under the top layer of conductor material that also has a plurality of holes that are not aligned with the holes in the top layer of conductor material. This allows gaseous HF to run in zig-zag fashion in order to be able to reach the area of the MEMS. The subsequent sealing of the etched hole arrays arranged in a zig-zag fashion is easier. The sealing may performed by depositing a metallic layer, and another passivation layer or WLCSP layer, where WLCSP typically includes Al sputtering.

In some embodiments, the passivation holes may have a size between 0.6 μm and 0.8 μm. Depending on the size of the holes on the top layer and the tilt of the wafer when performing the Al sputtering, it may be unnecessary to provide a layer below the top layer to stop the Al sputtered. For example, embodiments where the holes are on the order of 0.4 μm or less.

FIGS. 17-24C show process flow steps in an illustrative embodiment of the Al sputtering technique. The technique plugs the release holes with Al sputtering. In the proposed flow, a double passivation opening is performed, first one to etch the IMD and a second one for the normal pad openings. In some embodiments, a second passivation after the Al sputtering may be performed, to improve the protection. After this plugging any standard thin film packaging technology (e.g., WLCSP) may be used.

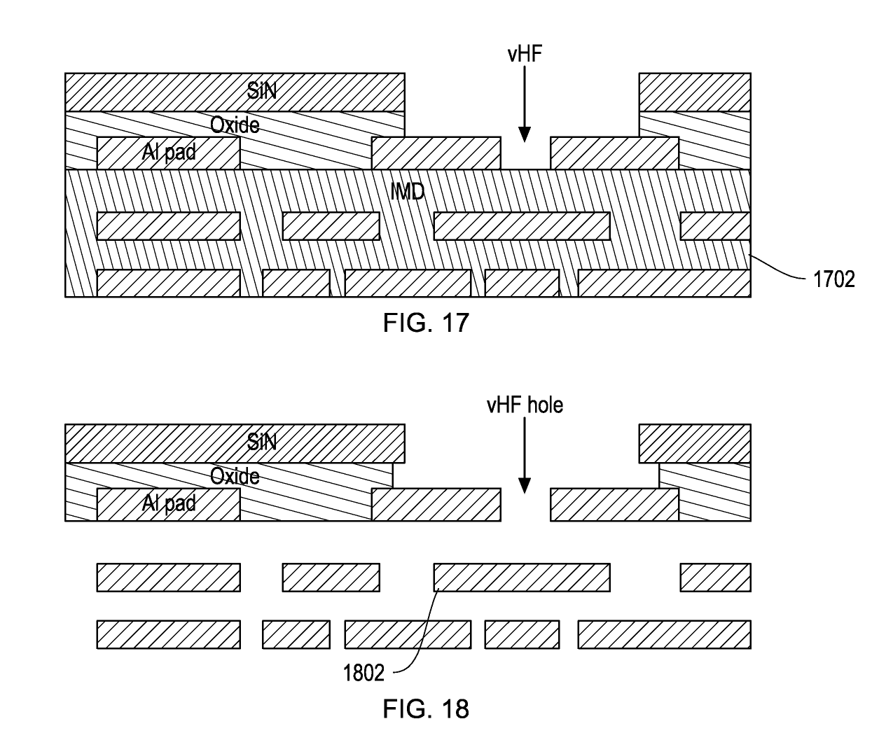

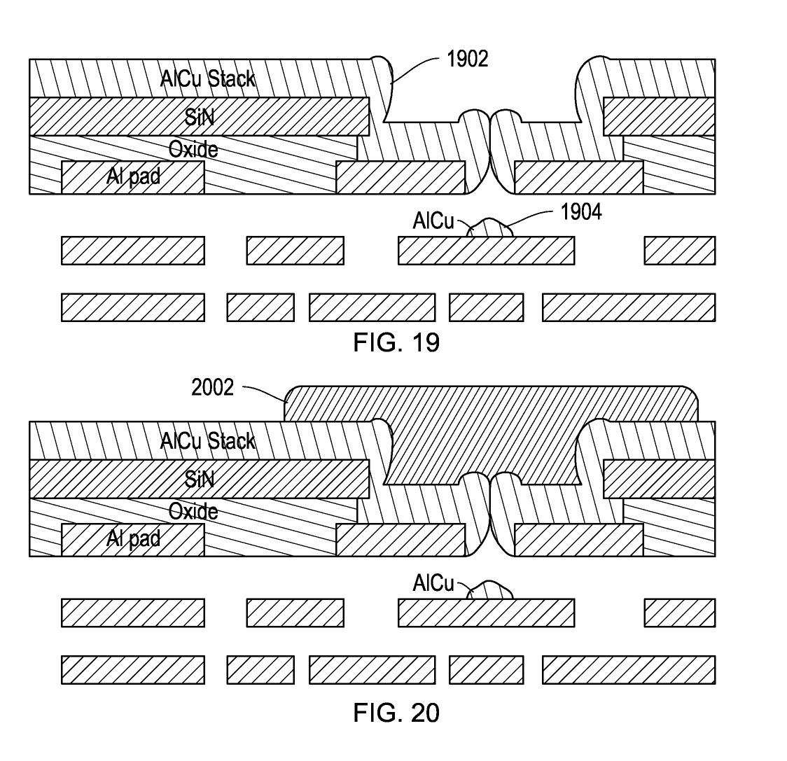

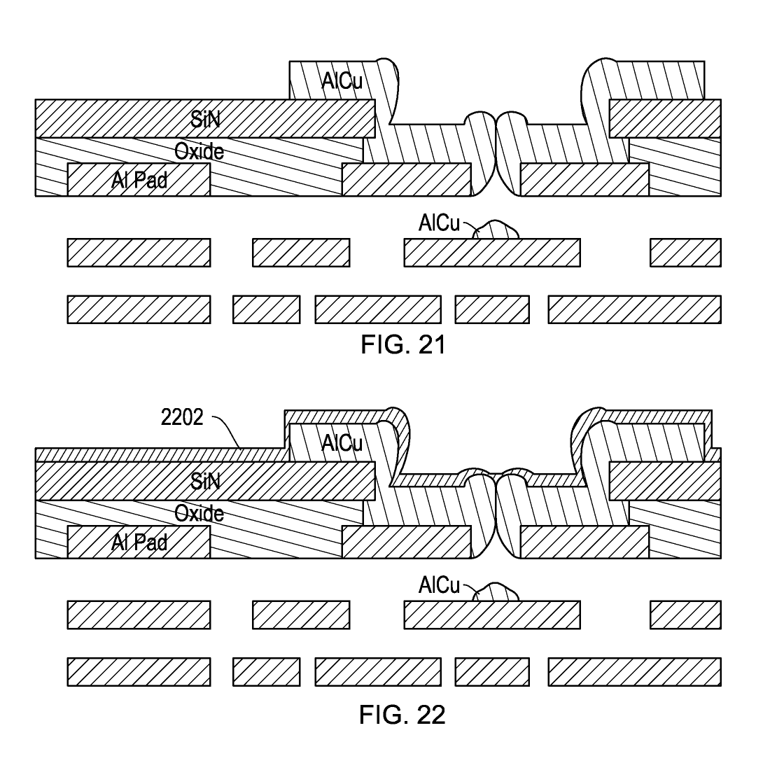

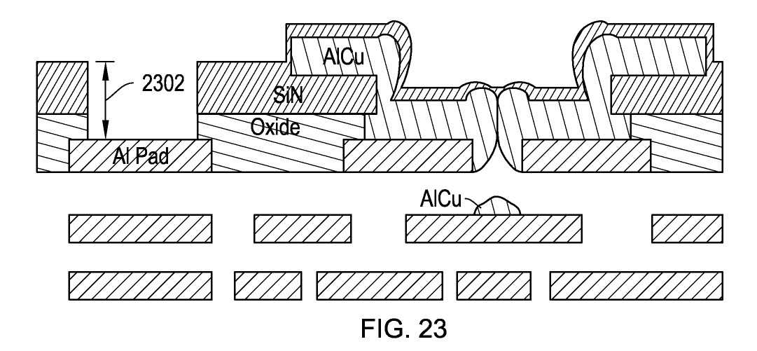

FIG. 17 shows a CMOS wafer with MEMS only release holes open in passivation, and with pads closed. Next, the wafer may be prebaked at, for example, 150° C., followed by release of vaporized HF, and post baked at 250° C. The vHF may etch away the IMD 1702 and leave behind the structure 1802 shown in FIG. 18. Next, a layer of Al or AlCu 1902 may sputtered on top of the whole wafer (FIG. 19). The wafer may be prebaked at, for example, 150° C., before the sputtering. FIG. 19 shows an instance where the AlCu extends through the hole and may be deposited on one of the lower layer elements. Applicant has observed that in certain instances, the Al or AlCu may form an upside down meniscus 1904 (e.g., crescent shape) from the hole in the SiN layer without contacting a lower layer element. Next, a film of photoresist material may be deposited, and then some of the material may be removed to form a photoresist mask 2002 on the Al plugged area (FIG. 20). Next, the sputtered Al layer may be etched away, and the photoresist mask may be removed (FIG. 21). A layer of SiN 2202 may be deposited on top of the whole wafer (FIG. 22). In some embodiments, the deposited SiN layer 2202 may have a thickness as high as 2.0 μm. Next, a photoresist mask may be developed for a pad opening, the passivation layer may be dry etched, and the photoresist mask may be removed. This creates the pad opening 2302 (FIG. 23). In some embodiments, the pad opening may have a thickness as high as 3.5 μm.

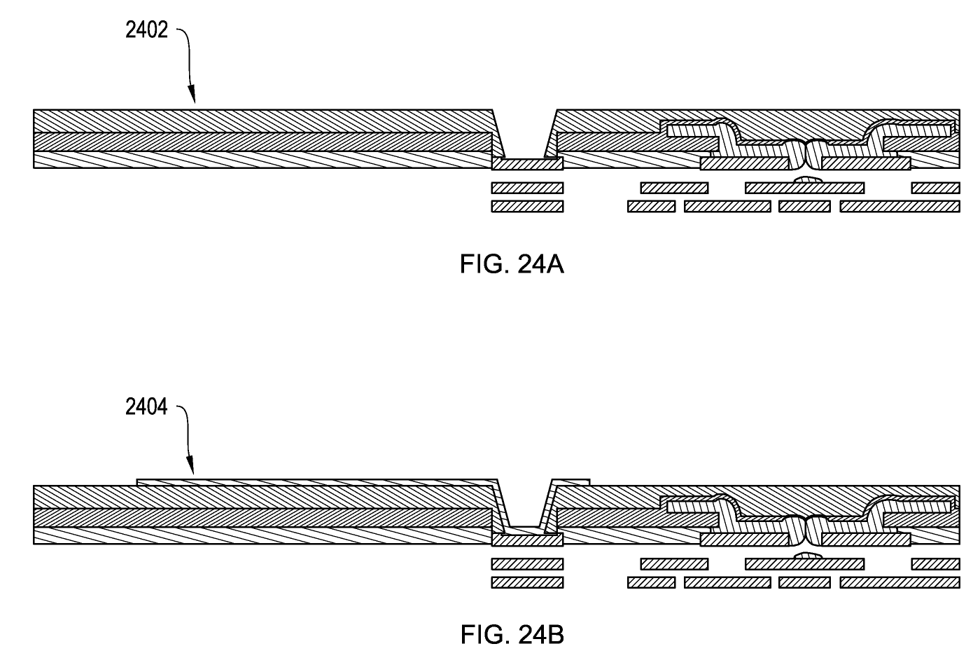

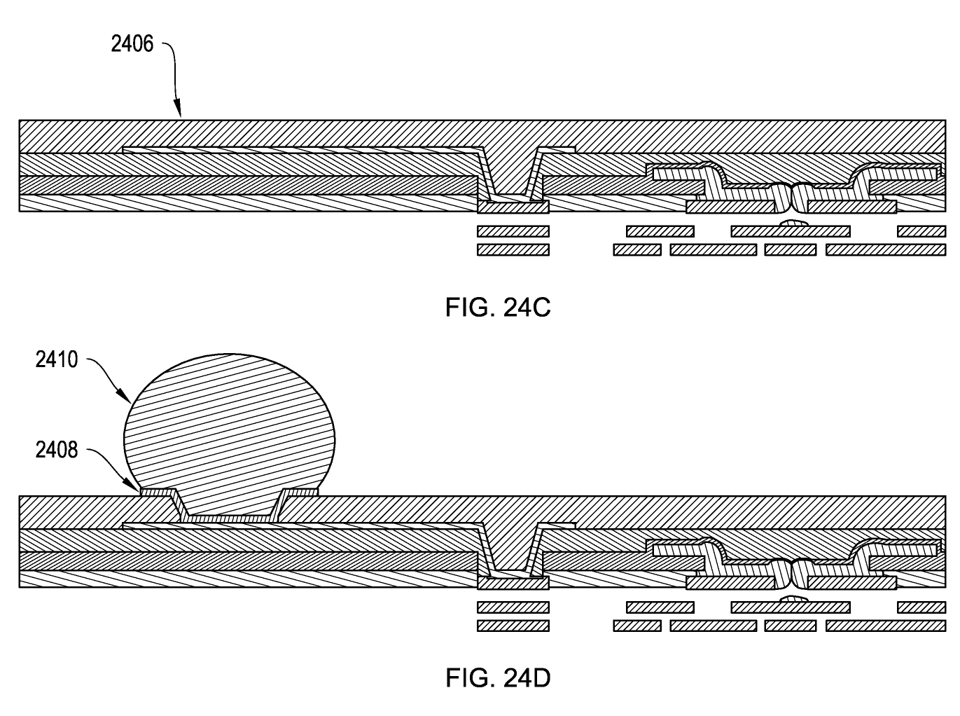

In some embodiments, WLCSP processing may be performed on the wafer, comprising an optional organic layer (polyimide or polymer), which may act as a stress buffer on the active die surface. An illustrative embodiment of the WLCSP packaging is shown in FIGS. 24A-24C. The polyimide covers the entire die area except for openings around the bond pads (polymer layer 2402 in FIG. 23). In some embodiments, the polyimide may have a thickness of 7.5 μm. An additional Redistribution Layer (RDL) of lateral connections may be employed to rearrange the peripheral wirebond connections in a manner suitable for wafer level processing (Cu RDL 2404 in FIG. 24B). The RDL may be fabricated from a thin layer of Al, AlCu, or Cu. In some embodiments, a Cu RDL may have a thickness of 5.0 μm. Another polyimide layer may be deposited to cover the entire die (polymer layer 2406 in FIG. 24C). In FIG. 24D, an under-bump metallurgy (UBM) layer 2408 may sputtered or plated over this opening. The UBM may comprise a stack of different metal layers serving as diffusion layer, barrier layer, wetting layer, and antioxidation layer. A solder ball 2410 may dropped over the UBM and reflowed to form a solder bump (FIG. 24). The wafer may then be subjected to a thermal flow process in an oven. The thermal treatment melts the solder ball and cools it in a well defined shape as shown in FIG. 24. The entire structure may be subject to thermo-mechanical stresses during the solder melt and subsequent solidification and cool down to room temperature. The forces may be severe enough to create cracks in the underlying passivation film. These cracks left in the passivation film may expose the underlying structures to the harmful ambient environment. It may allow moisture and other contaminants to penetrate the device structures through the cracks leading to circuit failure.

### Single Oxide Inter-Metal Dielectric

The manufacturing method of a chip comprising a MEMS arranged in an integrated circuit may include an interconnection stage, wherein a plurality of layers of conductor material are deposited. The conductor layers may be separated from one another by layers of inter metal dielectric (IMD) material. The dielectric material may be silicon dioxide or compounds derived from silicon dioxide. During HF attack, the double oxide that comprises the IMD may cause instability in the reaction due to the two oxides reacting to the HF at very different pressures and speeds. In some embodiments, a single oxide IMD may be used. This may allow for reduction of lateral overetch and cleaner contacts without residues.

### Scribe Line Modifications

Integrated circuit devices may be formed in multiples on semiconductor wafers and then diced into individual devices. The devices may have rectilinear shapes and may be formed in a matrix array on semiconductor wafers. Scribes may be drawn across the wafer surface to scribe a line or lines (called scribe lines) along which the wafer is eventually broken into individual dies. In some embodiments, the dicing operation involves scribing between the rows and columns of the devices on the semiconductor wafers using a dicing saw. The scribing is carried out on the active side of the semiconductor wafers where the devices are formed and the scribe lines are defined in the areas of the wafer between each individual device. In some embodiments, the wafer scribe lines may be covered with passivation to increase their height and to avoid sharp vertical edges.

### Chemical-Mechanical Polishing (CMP) of the Passivation Layer

Chemical-mechanical polishing (CMP) is a technique used in semiconductor fabrication for planarizing a semiconductor wafer or other substrate. In some embodiments, the process may use an abrasive and corrosive chemical slurry in conjunction with a polishing pad and retaining ring, typically of a greater diameter than the wafer. The pad and wafer are pressed together by a dynamic polishing head and held in place by a plastic retaining ring. The dynamic polishing head is rotated with different axes of rotation (i.e., not concentric). This removes material and tends to even out any irregular topography, making the wafer flat or planar. This may be necessary in order to set up the wafer for the formation of additional circuit elements. In some embodiments, CMP may be performed on the passivation layer during fabrication, to avoid cracks or thin points in the wafer.

### Modified RI SiN MIM Modules

In some embodiments, an MIM (Metal Insulator Metal) module may be implemented in order to produce high capacity capacitors in the CMOS process. The MIM module may comprise a silicon nitride (SiN). In some embodiments, an additional step may be carried out comprising adding a SiN layer with a modified refractive index (RI) followed by another metal layer. In some embodiments, the pre-existing SiN layer on the MIM may be modified to have a high RI before deposition. An SiN layer with an increased RI may etch slowly, allowing for electrically disconnected structures which may be mechanically connected.

### Finger Actuator

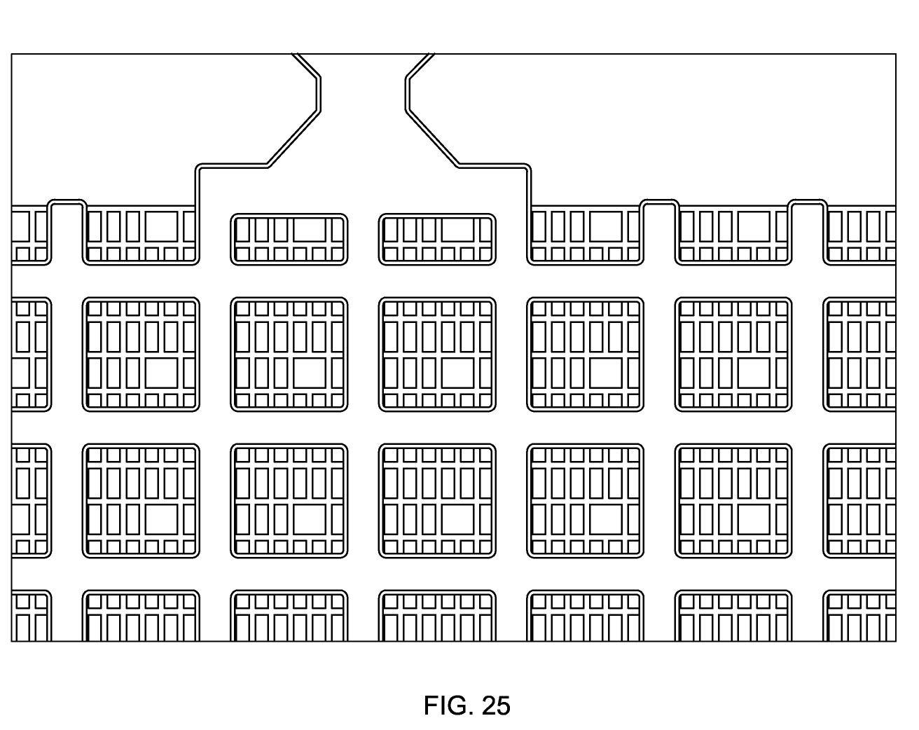

A finger actuator is a MEMS/NEMS actuator, comprising a mesh and vertical columns, or “fingers”, that fit between the mesh. The capacitance of the finger actuator may be varied by moving the mesh vertically. The capacitance may be higher than standard parallel plate capacitors. An increase in capacitance may allow for reduction in actuation voltage, larger actuation forces, and/or smaller actuator size. In some embodiments, the finger actuator may increase the static capacitance between two plates and/or the variation of the capacitance with respect to the distance between the plates. The capacitance variation with distance may provide the ability to customize force versus gap curves. In some embodiments, the finger actuator may exhibit lower dependence of electrostatic actuation force on plate gaps. As a result, the electrostatic force decay for large gaps may be smaller than standard parallel plate capacitors. The electrostatic force may be distributed in the (x,y) plane by varying the spatial distribution of dimensions, density, and length of the “fingers”. In some embodiments, the instability (pull-in) may be reduced substantially resulting in increased robustness of the device. In some embodiments, adding an integrated resistor in series with the fingers may reduce or eliminate destructive effects of breakdown voltage of the air. FIG. 25 shows an illustrative embodiment of the arrangement of a mesh and fingers in a finger actuator.

### Vibrating Antenna

While the foregoing describes one or more MEMS devices arranged using one more an integrated circuit fabrication techniques that may be employed for various types of applications, the applications discussed below should not be considered as limited to this type of process. The foregoing is one type of process to implement the applications given below.

It is known from classic antenna theory that a high performance antenna must have large physical dimensions compared to the electrical wavelength of the carrier frequency at which it is radiating. In practice, therefore, it is accepted that a compact antenna may not achieve good performance, specifically, good resolution, and also efficiency and bandwidth. To be able to resolve small objects well, the antenna needs to either use a high frequency or have large physical dimensions. These limitations are present since the antenna is a static radiating structure. There are many different types of antennas, for example, wire antennas, apertures and reflectors, as well as arrays of these types of antennas. Such antennas exhibit no change in their physical shapes over a period of time.

In recent years, use of MEMS-based switching and actuating devices or circuits has enhanced antennas. MEMS-based solutions may offer reduction in insertion loss, consume minimal power during operation, and provide lower signal distortion. MEMS may allow for fabrication of a device in a reduced die space. MEMS switches may reconfigure either the antenna matching network, or the antenna itself. The MEMS switches may either change the impedance values of the matching network, or join or isolate antenna parts. The MEMS switches may be varied over time as per the needs of the system containing the antenna. However, this use of MEMS technology still targets reconfiguration of static antennas. As a result, compact antennas face the same limitations and their performance does not improve with the use of MEMS technology like MEMS switches.

In order to overcome the size limitations inherent in static antennas, MEMS technology may be used to build an antenna that changes its shape over a period of time in two ways. The first way includes switching a set of fixed antennas or antenna parts via MEMS switches. The second way includes mechanically moving an antenna built using MEMS technology. The movement is typically accomplished via electrostatic forces, although the forces may be piezoelectric, magnetic, or thermal in nature. The moving structure interacts with electromagnetic waves to generate an output signal that may be sensed. This type of antenna is called a vibrating antenna. MEMS technology enables building vibrating antennas that vibrate them at frequencies up to the 100 kHz and more. However, MEMS technology is only one type of process to build vibrating antennas. The manufacture process of vibrating antennas need not be limited to MEMS technology. For example, vibrating antennas may be implemented as carbon nanotube-based nano-electro-mechanical systems (NEMS) devices.

In certain embodiments, a vibrating antenna achieves high performance by vibrating at a high frequency. Examples of high frequencies include cellphone frequencies (700-2100 MHz) and GPS satellite frequencies (1100-1600 MHz). In some embodiments, a vibrating antenna may operate at least at or above 400 MHz, 450 MHz, 500 MHz, 550 MHz, 600 MHz, 650 MHz, 700 MHz, 750 MHz, 800 MHz, 850 MHz, 900 MHz, 1000 MHz, 1500 MHz, 1900 MHz, 2.4 GHz, 5 GHz, 10 GHz. In one embodiment, the vibrating frequency is higher than either the carrier frequency, the bandwidth or the information bandwidth of the signal being radiated. Having the frequency of the periodic movement to be higher than the minimum operational bandwidth may help avoid undesired interferences. The exact requirements may depend on the vibrating antenna type including the following implemented signal processing.

In one embodiment, the present invention provides a type of vibrating antennas called a capacitive antenna. The invention includes a capacitive sensor, where current is passed through a moveable proof mass (e.g., a moveable plate) to interact with a magnetic field and produce a force orthogonal to both the current and the magnetic field. This produces a displacement field on the proof mass, detectable as a change in capacitance. The capacitive sensor may sense several different physical magnitudes, depending on how it is driven by an analog front end (AFE).

The capacitive sensor may behave as an accelerometer, a gyroscope, a magnetometer or a compass. In an illustrative embodiment where a capacitive sensor behaves as an accelerometer, a mass is oscillated by changing stiffness of springs attached to the mass. The oscillation is produced in the direction of the acceleration, and is proportional to the external acceleration. In an illustrative embodiment where a capacitive sensor behaves as a gyroscope, two oscillating voltages, 180° out of phase of each other, are applied to a mass. As the plane of oscillation of the vibrating mass is rotated, the measured capacitance change is proportional to the external rate of rotation. In an illustrative embodiment where a capacitive sensor behaves as a compass, two sinusoidal currents shifted 90° are applied in orthogonal directions to achieve the equivalent of a current with constant amplitude but continuous changing direction. The moment in time when the vertical movement peaks is recorded. The difference in capacitance due to proof mass displacement is also measured. The North or magnetic North direction is detected using the difference in capacitance, and the delay or phase difference between the moment in time oscillating currents are applied and the moment in time where vertical movement peaks. Similarly, for the x and y axes, two orthogonal and 90° shifted currents are applied, capacitance variations in the vertical and the two orthogonal axes are measured, and the one with a larger amplitude response is used. In an illustrative embodiment where a capacitive sensor behaves as a magnetometer, an AC current is applied to a mass such that vertical movement of the mass is produced. Measuring vertical movement allows measurement of the magnetic field in the direction orthogonal to the direction of the current. In some embodiments, the sensor may be duplicated multiple times to form a multisensor chip with different capabilities. In some embodiments, a multisensor chip may include only one capacitive sensor configured to measure different physical magnitudes at different moments in time. For example, a capacitive sensor in a MEMS circuit may be configured to operate as an accelerometer, a magnetometer, a gyroscope, or a compass at different instances in time. The capacitive sensor may be reconfigured over and over to offer different functionalities at different times. This gives a user the perception of having multiple sensors, while in reality only one sensor exists. In some embodiments, an AFE may be multiplexed for a plurality of capacitive sensors. For example, a MEMS integrated circuit comprising a plurality of vibrating antennas may be fabricated. At least one of the plurality of vibrating antennas may be activated by a signal from the AFE to operate as one of an accelerometer, a magnetometer, a gyroscope, and a compass.

The capacitive antenna may be modified to achieve better sensitivity by using a mechanically resonant structure, where the antenna vibrates at its mechanical resonant frequency. AC current may be passed through the resonant capacitive antenna at the mechanical resonant frequency. The mechanical quality factor, Q, may be increased by properly sealing the antenna in vacuum. The proof mass displacement and the capacitance variation are multiplied by Q. This may enable detection of smaller magnetic fields by the AFE, at a more efficient increase in power consumption.

Capacitive antennas, implemented as MEMS devices, may be used in a multitude of applications. For example, multiband antennas for wireless devices (e.g., cellular telephones) that are small in size and deliver high performance. In such embodiments, the capacitive antenna may be for reception only. Capacitive antennas may also be used in anti-theft and/or shop lifting detection devices. The antenna may be combined with an energy scavenging device (based on, for example, solar power, radio waves, vibrations, or temperature) to form a low price, autonomous, ultra small chip. This chip may be embedded into goods to sense electromagnetic waves at very low frequencies. Without a capacitive antenna, the working frequency for a miniature antenna in the chip would be higher, and higher frequency electromagnetic waves may be easily shielded by a potential thief using, for example, aluminium foil.

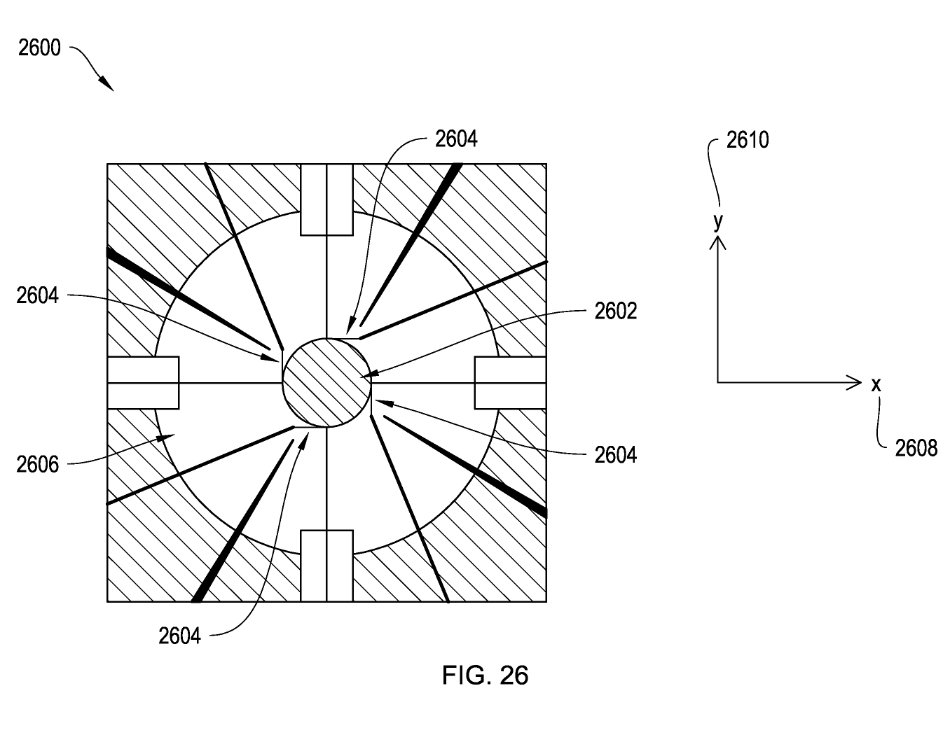

FIG. 26 shows an illustrative embodiment of a resonant capacitive antenna implemented as a MEMS device. FIG. 26 shows the device as cylindrical proof mass 2602 made with a stack-up of metal layers M2-M6, including via layers. The proof mass does not include metal layer M1. M1 is typically a protection layer covering the device underneath (to avoid vHF from reaching the ILD below M1). The device is suspended by four springs 2604 of length 30 μm each present in metal layer M4 only. Guard area 2606 measuring 100 μm is covered by metal layer M1. Neither pads nor the release layer are shown in the figure.

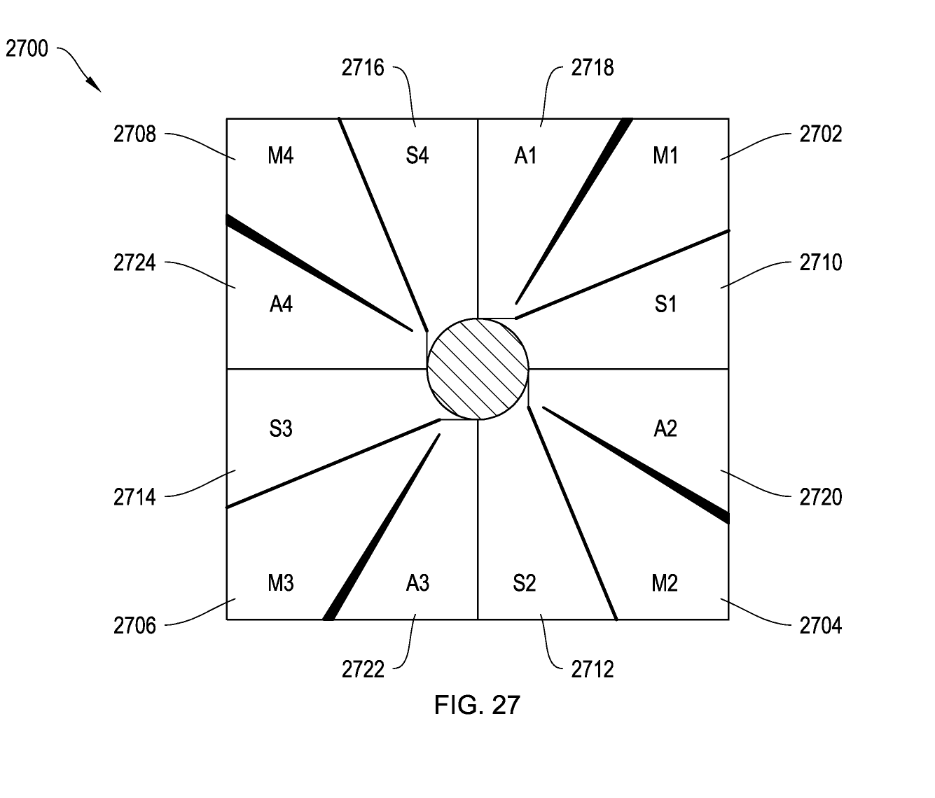

FIG. 27 shows a top view of the resonant capacitive antenna implemented as a MEMS device. The device has sixteen signals, 2702-2720. Signals S1-S4 (2710-2716) sense capacitance between electrodes and the proof mass. Signals M1-M4 (2702-2708) are connections to moveable proof mass 2602 (FIG. 26) through springs 2604 (FIG. 26). Signals A1-A4 (2718-2724) are electrostatic actuators that move the springs horizontally. The actuators drive the mass into resonance when sensing accelerations (linear and angular).

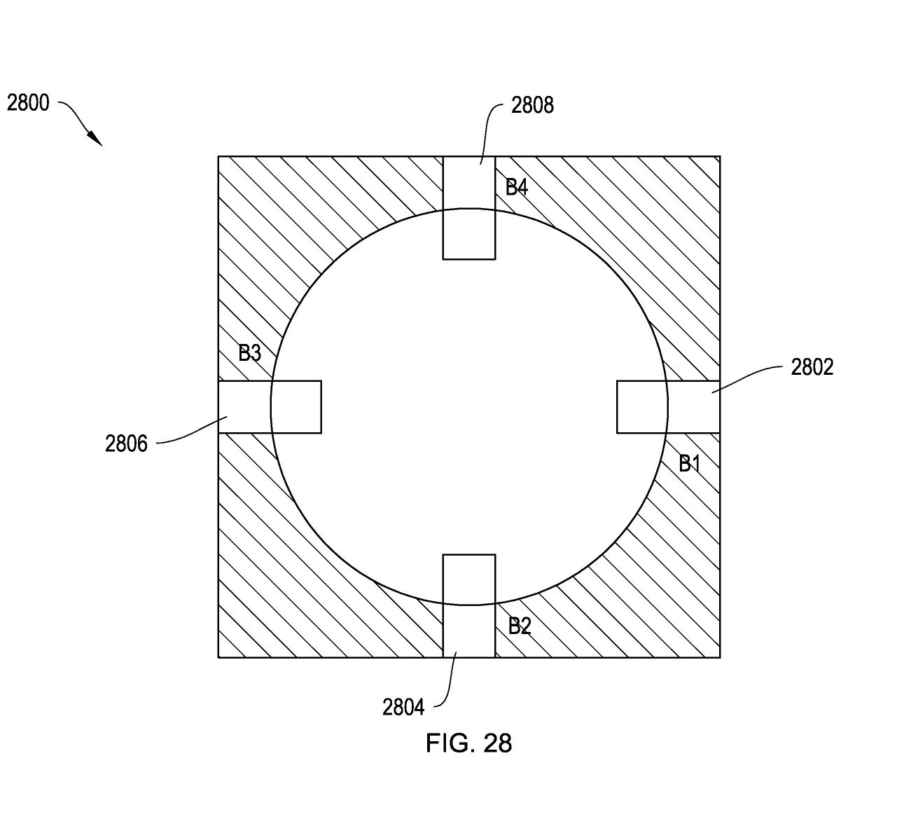

FIG. 28 shows metal layer M1 of the resonant capacitive antenna implemented as a MEMS device. Signals B1-B4 (2802-2808) are bottom connections to metal layer M1. Signal B1-B4 (2802-2808) sense the capacitance between M1 and proof mass 2602 (FIG. 26) on top, drive mass 2602 (FIG. 26) into resonance when sensing accelerations, or produce current flow through metal layers M1-M4 (2702-2708, FIG. 27).

In the illustrated embodiment, differential capacitance is measurable only in the x and y horizontal directions. Non-differential capacitance change may be measured in the z direction. The capacitive antenna MEMS device has the following parameters:

g_{V}=0.9 μm (0.1)

g_{H}=0.5 μm (0.2)

k_{V}=k_{H}=k=2 N/m (0.3)

m=9.10⁻¹¹ kg (0.4)

C_{H}=C_{V}=C_{O}=100 fF (0.5)

where,
g_{V}, vertical gap between M1 and proof mass 2602 (starting at M2)
g_{H}, horizontal gap between proof mass 2602 and S electrodes (2710-2716)
k, mechanical restoring constant
m, mass of proof mass 2602
C_{H}, horizontal base capacitance
C_{V}, vertical base capacitance

In some embodiments, one or more plates may be added on top of proof mass 2602 (FIG. 26) to produce differential capacitance in at least one direction, e.g., the z direction. In some embodiments, an additional mass may added to proof mass 2602 (FIG. 26) to achieve a desired Q value. In some embodiments, two different capacitances in opposite directions may be provided by shorting in parallel a second MEMS device with the top and bottom positions interchanged, and correspondingly changing directions for the horizontal axis.

In some embodiments, a resonant capacitive sensor may sense physical magnitudes corresponding to the behavior of an accelerometer. Appropriately applied signals to springs connected to proof mass 2602 (FIG. 26) produce movement of the proof mass. Measuring differential capacitance between electrodes and proof mass 2602 (FIG. 26) allows sensing of the physical magnitude corresponding to movement of the proof mass. This behavior is achieved by periodically changing the mechanical restoring force or stiffness of springs 2604 (FIG. 26) that sustain proof mass 2602 (FIG. 26). In some embodiments, stiffness may be changed periodically by passing an AC current at the mechanical resonant frequency through the springs. In some embodiments, stiffness may be changed periodically by applying an oscillating voltage at the mechanical resonant frequency through the springs. In some embodiments, stiffness may be changed periodically by passing an AC signal through the springs, such that the signal heats the springs up and down via Joule effect. This may allow the temperature of a spring to follow the current variation across the spring. In some embodiments, stiffness may be changed periodically by electrostatically stimulating a mechanical spring. This may be done for small displacements by adding two electrostatic electrodes at each side of the moveable plate. Achieving resonance by means of periodically changing the stiffness of the springs by some means (electrostatic or thermal) is a known technique, called “parametric amplification”. Though such techniques amplify the displacement of the proof mass, they may lead to instabilities. Care may need be needed to properly design the capacitive sensor in order to avoid such instabilities.

The periodic change in stiffness of the springs produces an oscillation of mass 2602 (FIG. 26) in the direction of the acceleration produced, proportional to the external acceleration. The acceleration produced is increased by a factor proportional to the Q value. The factor may be approximated as equal to the Q value, as a first approximation. Proof mass 2602 (FIG. 26) may be connected to ground through signals M1-M4 (2702-2708). To sense acceleration in the z direction, an oscillating voltage may be applied to signals A1-A4 (2718-2724, FIG. 27). To sense acceleration in the x direction, an oscillating voltage may be applied to signals A2 (2720, FIG. 27) and A4 (2724, FIG. 27). To sense acceleration in the y direction, an oscillating voltage may be applied to signals Al (2718, FIG. 27) and A3 (2722, FIG. 27).

In some embodiments, a resonant capacitive sensor may sense physical magnitudes corresponding to the behavior of a gyroscope. This is accomplished using the coriolis force principle. The AFE may be almost the same as that for the resonant capacitive antenna to behave as an accelerometer. The AFE induces a vibration on proof mass 2602 (FIG. 26) by applying an oscillating voltage to signals A1-A4 (2718-2724, FIG. 27). In addition, the AFE produces an orthogonal vibration on proof mass 2602 (FIG. 26) by applying another oscillating voltage to signals A1-A4 (2718-2724, FIG. 27) that is 180° out of phase from the aforementioned voltage. The AFE may use signals B1-B4 for a vibration needed in the vertical (z) direction.

In one embodiment, a resonant capacitive sensor may sense physical magnitudes corresponding to the behavior of a compass. The antenna senses the direction of the magnetic field, as opposed to its strength. Two sinusoidal currents, one applied between metal layers M1 (2702, FIG. 27) and M3 (2706, FIG. 27), and the other applied between metal layers M2 (2704, FIG. 27) and M4 (2708, FIG. 27), achieve the equivalent of a current with constant amplitude but continuous changing direction. The current rotates parallel to the substrate. The moment in time when the vertical movement peaks is recorded. This happens as a result of the current being aligned with the Earth's magnetic field. The difference in capacitance due to proof mass displacement is also measured. The North direction is detected using the difference in capacitance, and the delay or phase difference between the moment in time oscillating currents are applied and the moment in time where vertical movement peaks. The currents oscillate at the mechanical resonant frequency. In some embodiments, the currents oscillate at a frequency lower than the mechanical resonant frequency.

In certain embodiments, a resonant capacitive sensor may sense physical magnitudes corresponding to the behavior of a magnetometer. An AC current at the mechanical resonant frequency may be applied to proof mass 2602 (FIG. 26). Applying the current between metal layers M2 (2704, FIG. 27) and M4 (2708, FIG. 27) and sensing vertical movement allows measurement of the magnetic field in x direction (2608, FIG. 26). Applying the current between metal layers M1 (2702, FIG. 27) and M3 (2706, FIG. 27) and sensing vertical movement allows measurement of the magnetic field in y direction (2610, FIG. 26). Applying the current between metal layers M2 (2704, FIG. 27) and M4 (2708, FIG. 27), or between metal layers M1 (2702, FIG. 27) and M3 (2706, FIG. 27), and sensing horizontal movement allows measurement of the magnetic field in the z direction.

The magnetometer may not give accurate measurements if the proof mass is exactly and continuously orthogonal to the magnetic field. This may not be an issue in a handheld application (e.g., a cellphone) since a person may not be able to keep the cellphone fixed with such a degree of accuracy. This also may not be an issue if the capacitance variation is measured in all three axes. However, in applications where this may be of concern, an electrostatic force may be applied to tilt the proof mass in order to obtain accurate measurements.

### Integrated Inductor

While the foregoing describes one or more MEMS devices arranged using one more an integrated circuit fabrication techniques that may be employed for various types of applications, the applications discussed below should not be considered as limited to this type of process. The foregoing is one type of process to implement the applications given below.

It has become advantageous to use on-chip inductors in radio frequency (RF) integrated circuits. Particularly, oscillators need inductors to achieve high performance. In LC oscillators, the quality factor Q of an inductor may be critical to phase noise performance. Since the self-resonance frequency of the inductor may limit the operating frequency and/or the tuning range of the oscillator, careful optimization may be required. As transistors scale to smaller geometries, their associated supply voltages may need to be reduced. Since inductors have almost zero DC voltage drop, they may be used to increase voltage headroom in low voltage RF circuits. For cross-coupled differential pair LC oscillators, an inductor at the source node of the differential pair may increase signal headroom. In embodiments where the inductor resonates at twice the oscillation frequency, noise performance may be significantly improved. Gain and noise factors of low noise amplifiers and mixers may also be improved by using inductors to tune out parasitic capacitances.

The Q factor is an important characteristic for inductors. The energy dissipation in an inductor depends on its Q factor. As the Q factor of an inductor increases, its energy dissipation decreases. MEMS-based technology may be used to enhance the Q factor of an inductor. For example, when fabricated using a MEMS CMOS technique, such inductors can have a large inductance value, high Q factor, and are easy to mass produce.

In some embodiments, MEMS CMOS technology may be used to fabricate an integrated inductor having a large inductance value, and a high Q factor. The MEMS inside CMOS process typically produces a curvature. This curvature depends on the specific CMOS process, and is usually quite large. Therefore, a single top metal layer may have a radius as low as 30 μm. The radius of the metal layer may be, without limitation, at least 10 μm, 15 μm, 20 μm, 25 μm, 30 μm, 50 μm, 100 μm, 150 μm, 200 μm, 250 μm, or 300 μm. In some embodiments, an integrated inductor may be fabricated as a long track of a single metal layer, at least 1 mm or more. In some embodiments, an integrated inductor may be fabricated as a long track of a single metal layer with a length less than 1 mm. After release by etching the surrounding inter metal dielectric (IMD), the metal layer bends and may have many turns at the end.

The process may potentially be done on any metal layer. In some embodiments, a metal top layer is chosen since such a layer may bend more. In some embodiments, a metal layer under a top metal layer, and without top metal layer above it, may be used. Such a metal layer may be thinner due to the etching process to make the pad opening, and may show more curvature when released. However, the inductance value does not depend on the curvature radius. A larger radius leads to fewer turns, but a larger area for each turn. A smaller radius leads to more turns, but a reduced area for each turn. This may be beneficial since the curvature radius may vary due to factors during fabrication, but the variation in inductance value of the inductor may be minimally affected.

In order to have a coil, the other end of the layer needs to be fixed. In some embodiments, two lines of metal from the metal layer may be used that are connected at one end of the inductor. The lines need to be separated as much as possible, since the current flows in opposite directions on the two lines, and the magnetic fields may cancel. In some embodiments, the metal layer may be positioned on top of another pad, and wound on the pad after release. This is possible since at each turn the metal layer may displace horizontally as well. At one end, it may be positioned on top of another pad, given an appropriately calculated length of the layer, or a pad large enough to take into account the variations of the curvature. This end may be wound on the pad after release by applying a high current pulse.

Obtaining a transformer with a large inductance value may be difficult using planar inductors. However, using integrated inductors as disclosed in this document may allow for a transformer with a large inductance value. In some embodiments, two or more integrated inductors may be coupled to obtain an integrated transformer.

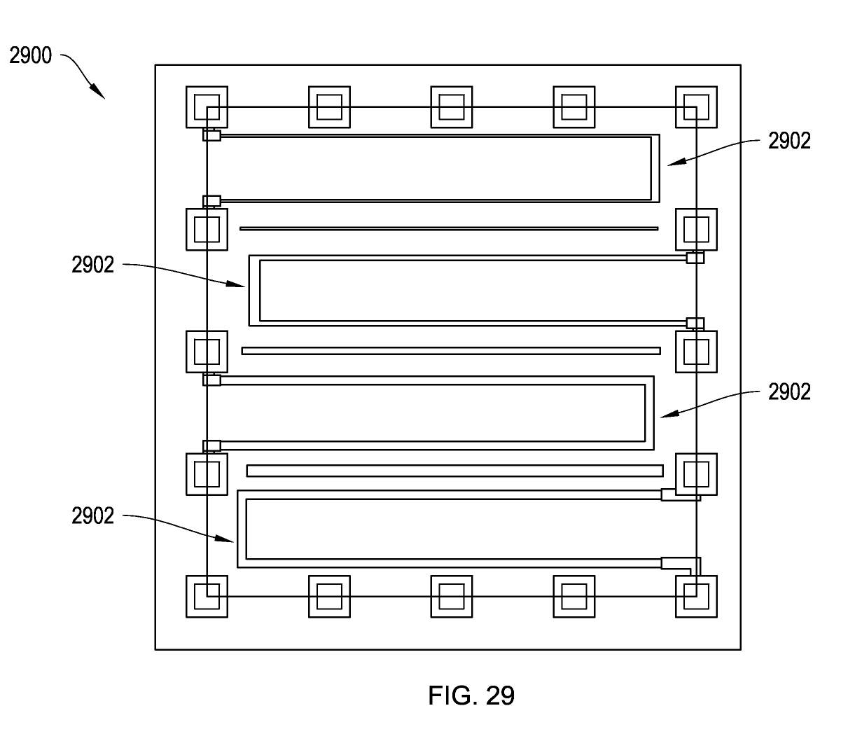

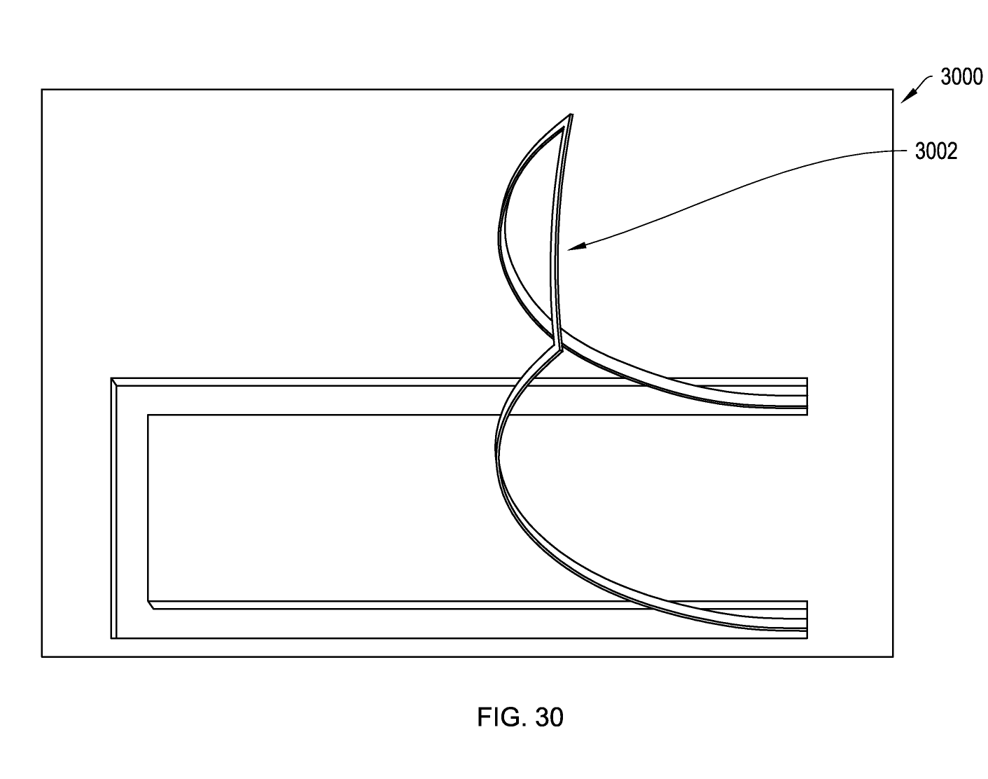

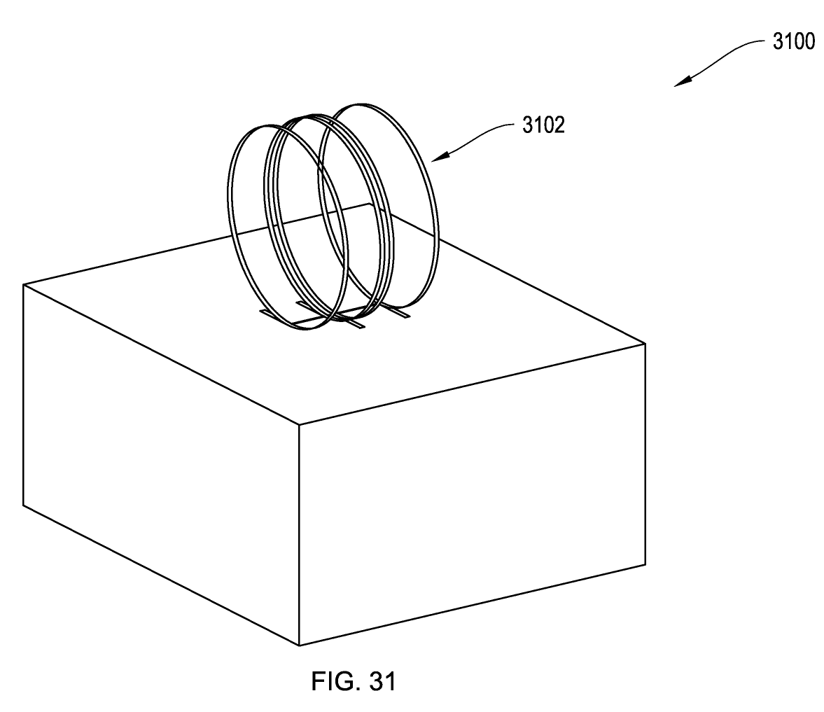

FIG. 29 shows an illustrative embodiment of a layout of a die containing integrated inductors. Die 2900 contains integrated inductors 2902, and some other test structures. FIG. 30 shows an illustrative Scanning Electron Microscope (SEM) image after release of integrated inductor 3002 from the surface of the chip. The curvature of the released metal layer is clearly visible. The process disclosed above allows for the fabrication of an integrated inductor on the surface of a chip having large inductance value, as well as a high Q factor. In some embodiments, a wafer bonding packaging scheme may be used for to accommodate the large height of the inductors on the surface of the chip. FIG. 31 shows an illustrative embodiment of an integrated transformer 3100, comprising three integrated inductors 3102.

### Modal Switch

While the foregoing describes one or more MEMS devices arranged using one more an integrated circuit fabrication techniques that may be employed for various types of applications, the applications discussed below should not be considered as limited to this type of process. The foregoing is one type of process to implement the applications given below.

The complexity of high-frequency systems is increasing as a result of higher performance requirements. Such complex systems include scientific instruments that are part of satellite payloads and require high precision and resolution. Other requirements include low power consumption, weight and cost. The invention introduces a new type of switch, a modal switch. A modal switch may be ohmic, capacitive, or a combination of both. Such switches offer several advantages including lower voltage across tunable impedances, high isolation, and low power consumption. Modal switches are based on the idea that the actuator may make a change on the EM field distribution (or mode). The shape of the circuit may permit certain modes, but not others.

MEMS switches provide several advantages over conventional switches including low power consumption, low insertion loss, and a high degree of miniaturization. Since this type of switch is fabricated using existing integrated circuit processing technologies, production costs are relatively low. MEMS technology demonstrates great potential for fabrication of devices like the modal switch. For example, electrostatically actuated MEMS switches may conduct RF current in applications involving tuning of reconfigurable antenna elements, and in the fabrication of tunable filters. Accordingly, there are several advantages to implementing transmission line switches in MEMS-based or other chip-based technologies.

Switches may be classified by type of contact, or configuration. According to their type of contact, switches may be ohmic (metal-to-metal contact) or capacitive (switching by means of a variable capacitance). According to their configuration, switches may be: series (metal-to-metal contact or a large capacitance when the switch is ON), or shunt (no metal-to-metal contact or a small capacitance when the switch is ON). An object of the invention is to introduce a new type of switch configuration, modal. A modal switch may be ohmic, capacitive, or a combination of both. Modal switches are based on the idea that the actuator may make a change on the EM field distribution (or mode). The shape of the circuit may permit certain modes, but not others. Modes may be changed by a change in the geometry of the circuit, or by loading the circuit with lumped impedances. In some embodiments, modal or multimodal switches replace ohmic contact switches in uniplanar transmission lines.

Such switches offer several advantages including lower voltage across tunable impedances, high isolation, and low power consumption. Low power consumption is also an advantage especially for a MEMS implementation. In some embodiments, a modal switch is a transition between two types of uniplanar transmission lines, coplanar waveguides (CPWs) and slotlines or coplanar strips. The modal switch includes a tunable structure implemented as one or more tunable loads, series and/or shunt connected, on the transmission line. Power may be switched between modes depending on the asymmetry of the load values. The tunable structure may include loads in series, shunt, or a combination of both. This structure acts like a tunable impedance, implemented either as a resistance in an ohmic configuration, or as a tunable capacitor in a capacitive configuration, or a combination of both. A modal switch instead of cutting or bouncing power at a given point, transfers from one mode to another. If a section of the transmission line does not allow one of the modes, then transferring to that mode is equivalent to cutting the signal.

In one embodiment, a signal transmission system includes a first signal medium or path capable of transferring an electrical signal in at least two modes. The system also includes a second signal medium or path capable of transferring an electrical signal in one mode. The form of a signal medium may determine the mode in which the medium operates. For example, an electrical circuit may use a single-wire signal line and common ground as a signal medium. Alternatively, the circuit may use a dual-wire and/or differential signal line as a signal medium whereby signal information is based on the different in potential between the two lines, such as a slotline. Another type of signal medium may include three lines, such as a CPW transmission line.

In certain embodiments, a first signal medium is connected with and/or in electrical communication with a second signal medium. The first signal medium supports or propagates a first mode and second mode of signal transmission. The second signal medium only supports the first mode of signal transmission. A modal control mechanism controls the mode of the first signal medium. By changing the mode of signal transmission of the first signal medium to the first mode, the mode of transmission of the first and second medium are the same, allowing any signal carried by the first signal medium to be transmitted to the second signal medium. By changing the mode of signal transmission of the first signal medium to the second mode, the mode of transmission of the first and second are different, preventing any signal carried by the first signal medium to be transmitted to the second signal medium. In some embodiments, the controller may be arranged in an integrated circuit. The controller may include a MEMS or a CMOS structure.

A tunable impedance may allow for operation of the modal switch as a tunable filter. In some embodiments, a modal transition between a balanced mode (CPW even mode) and an unbalanced mode (odd mode, or slotline mode) in combination with strategically placed series and shunt resonances may result in high isolation with relatively low Q values for inductors and capacitors. Such a tunable filter may be useful in diplexers/duplexers and RF filters found in cellphones for new generation modulations. It may achieve low losses in the pass band and large attenuation on the stop band, with a very narrow transition band. The attenuation on the stop band may be much higher compared to attenuation achieved with conventional technology.

MEMS switches provide several advantages over conventional switches including low power consumption, low insertion loss, and a high degree of miniaturization. Since this type of switch is fabricated using existing integrated circuit processing technologies, production costs are relatively low. MEMS technology demonstrates great potential for fabrication of devices like the modal switch. For example, electrostatically actuated MEMS switches may conduct RF current in applications involving tuning of reconfigurable antenna elements, and in the fabrication of tunable filters. Accordingly, there are several advantages to implementing transmission line switches in MEMS-based or other chip-based technologies.

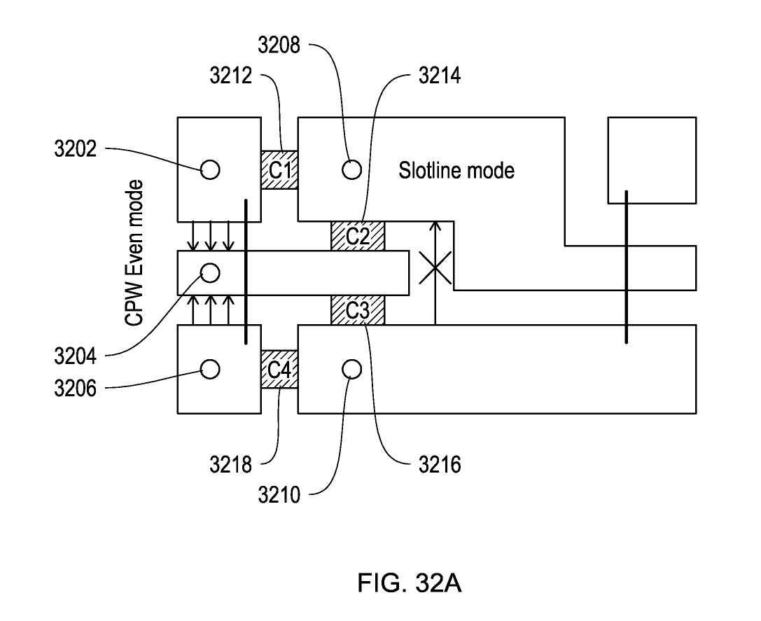

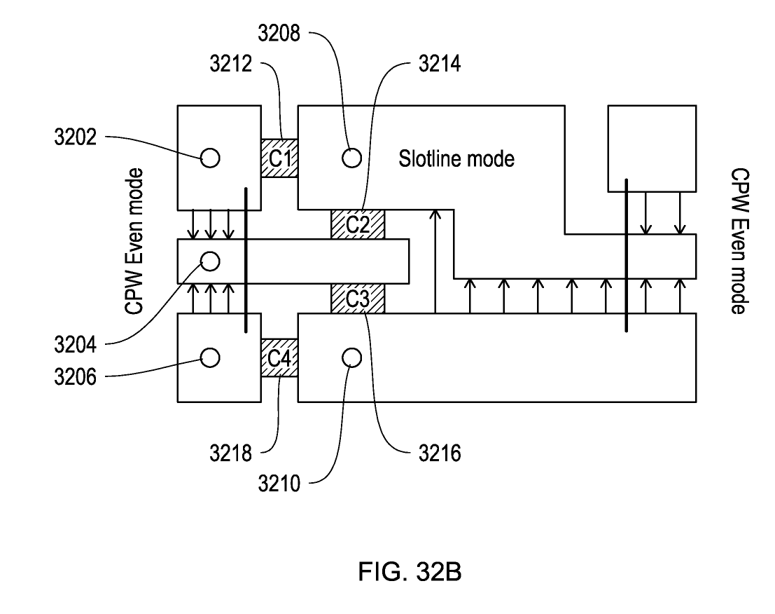

FIGS. 32A and 32B show an illustrative embodiment of a modal switch. FIG. 32A is a diagrammatical top view of the modal switch in the OFF state. FIG. 32B is a diagrammatical top view of the modal switch in the ON state. The switch is a CPW-to-slotline transition in a back-to-back configuration passing from an unbalanced (CPW even mode) state to a balanced state (CPW odd mode, or slotline mode). In the illustrative embodiment, CPW ground planes 3202 and 3206, and central conductor 3204, are electrically connected by capacitors C1 (3212), C2 (3214), C3 (3216), and C4 (3218). Selecting certain values for the different capacitors may result in a perfect short for the odd mode (or slotline mode), while allowing for operation of CPW even mode. In the OFF state, the power dividers implemented by the capacitors provide the same voltage in strips 3208 and 3210 where the slotline mode has to propagate, preventing signal propagation. In the ON state the structure behaves as a perfect modal transition between the CPW even mode and the slotline mode by connecting ground plane 3206 to strip 3210 of the slotline mode (via capacitor C4), and CPW central conductor 3204 to strip 3208 of the slotline (via capacitor C2), while capacitors C1 and C3 behave as an open circuit for the RF signal. Capacitors C1 (3212), C2 (3214), C3 (3216), and C4 (3218) connected as described above act as a modal control mechanism for this particular configuration of a modal switch.

In the illustrative embodiment, the CPW odd mode may be short-circuited without short-circuiting the CPW even mode. In embodiments where the four capacitors are of the same value, a frequency independent perfect isolation may be obtained for the switch in the OFF state. In some embodiments, isolation may be obtained if the value of C2 equals the value of C3, and the value of C1 equals the value of C4. The capacitance ratio (Cₒₙ/C_{off}) of a modal switch may be an order of magnitude lower than a conventional series capacitive switch for modest OFF state isolation and ON state insertion loss. Such a capacitive modal switch may be suited for a capacitive switch implementation at low frequency. There may be multiple configurations of asymmetric loads, including capacitive or resistive elements, or a combination of both.

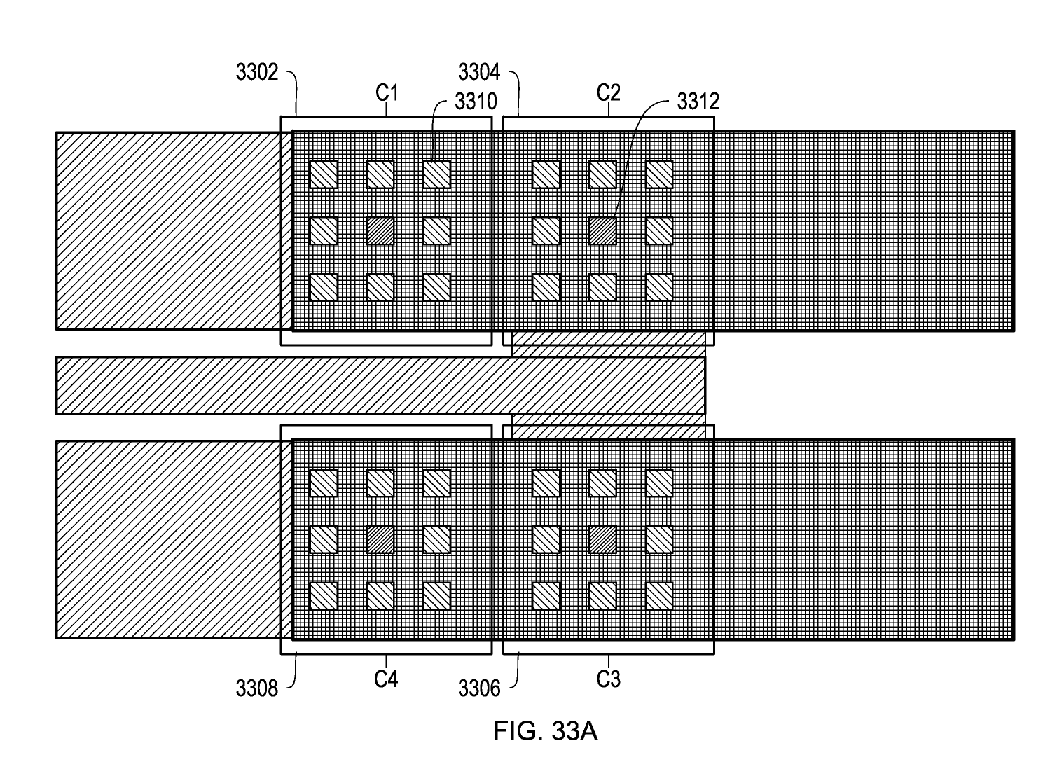

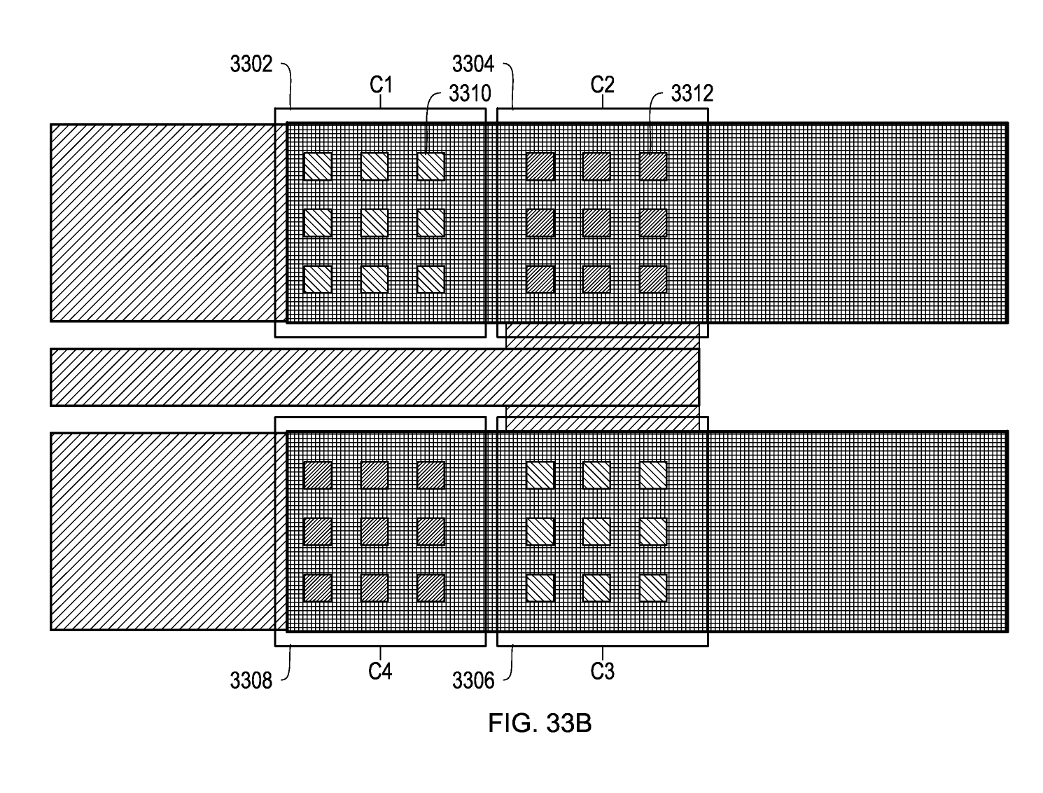

FIGS. 33A and 33B show an illustrative embodiment of variable capacitors (e.g., 3212 in FIG. 32) for a modal switch. FIG. 33A is a diagrammatical top view of modal switch variable capacitors, in the OFF state. FIG. 33B is a diagrammatical top view of modal switch variable capacitors, in the ON state. In this illustrative embodiment, capacitors C1 (3302), C2 (3304), C3 (3306), and C4 (3308) contain small capacitive unit cells. Each capacitive unit cell has a capacitance of 10 fF when deactivated (e.g., 3310), and 900 fF when actuated (e.g., 3333). Small capacitor cells present advantages such as smaller dielectric charging area, power handling capability, and reduced self actuation. Low actuation voltage may be necessary to minimize dielectric charging. The cells may be replicated as necessary in the RF design to obtain the desired capacitance value. The obtained value may be more accurate if cells present the same capacitance value, as well as the same parasitics.

In FIG. 33A, the modal switch is in the OFF state. Capacitor C1 is comprised of nine unit cells. When only one unit cell is actuated (e.g., 3312), capacitor C1 has a capacitance of 900 fF+8*10 fF=980 fF, which may be approximated to 1 pF. Similarly, capacitors C2-C4 also have a capacitance of approximately 1 pF when the modal switch is OFF. The symmetry of the layout of unit cells in the capacitor structure allows for good isolation behavior in the OFF state.

In FIG. 33B, the modal switch is in the ON state. Capacitors C1 and C3 have all cells deactivated, while capacitors C2 and C4 have all cells actuated. Each of C1 and C3 have a capacitance of 10 fF*9=90 fF, which may be approximated to 0.1 pF. Each of C2 and C4 have a capacitance of 900 fF*9=8100 fF, which may be approximated to 10 pF. Such a value may be required to achieve reasonable insertion loss behavior. The capacitance ratio (Cₒₙ/C_{off}) of the modal switch is approximately 10 pF/1 pF=10. This capacitance ratio is an order of magnitude lower than the capacitance ratio for a conventional series capacitive switch. In some embodiments, the capacitance ratio (Cₒₙ/C_{off}) of the modal switch may be less than 10. Parasitics may not be as important in the ON state, as for the OFF state. In the illustrative embodiment, some capacitive unit cells on C1 and C3 may not be used, but are needed for symmetry purposes. Additionally, isolation in the OFF state may not be degraded given parasitic capacitances that are symmetrical.

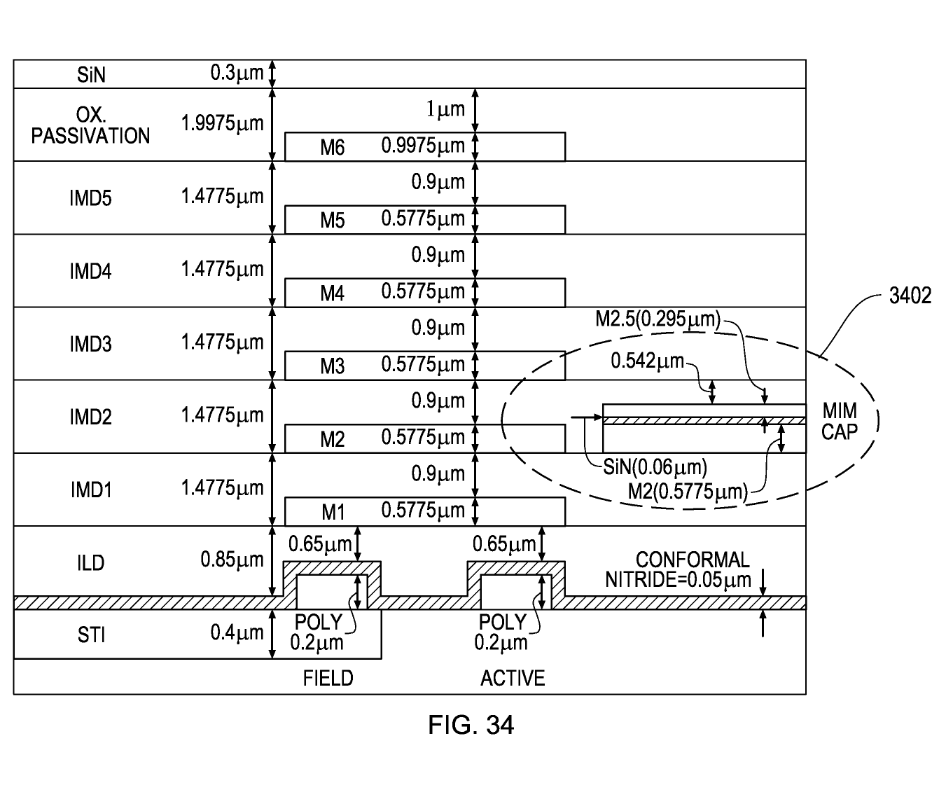

In some embodiments, a variable capacitor may be implemented in a CMOS process with Metal Insulator Metal (MIM) structure modifications. FIG. 34 is a diagrammatical cross-sectional view of an illustrative embodiment of a variable capacitor implemented in a one-poly six-metal (1P6M) CMOS process with MIM structure 3402. The MIM structure is discussed further below. The MIM structures may help achieve high density capacitance. For example, the MIM structure shown in FIG. 34 has a capacitance density of 1 fF/μm². A value of 10 pF may be obtained with such MIM structures in an area of 100×100 μm². The area may increase to 200×200 μm², taking into account area for actuation electrodes, and the possibility of less than perfect capacitive contact. Therefore, four capacitors for the modal switch may be obtained in an area of 400×400 μm², approximately.

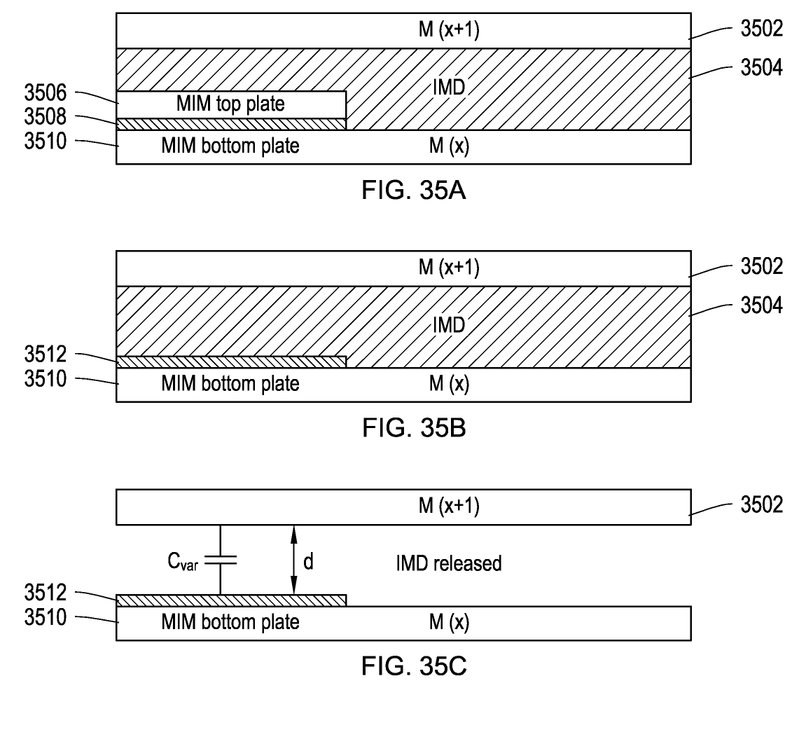

FIG. 35 shows illustrative embodiments of MIM structure 3402 (FIG. 34). FIG. 35A shows a conventional MIM structure with plates M(x) (3502) and M(x+1) (3510) at the top and bottom, respectively. In between plates M(x+1) and M(x), lie inter metal dielectric (IMD) layer 3504, MIM top plate 3506, and silicon nitride (SiN) layer 3508. In order to implement a capacitor (or a capacitive switch) with high capacitance ratio between the deactivated and actuated states, at least two changes may be required. The MIM insulator SiN layer 3508 needs to have a refractive index (RI) of 2.5. Additionally, MIM top plate 3506 need not be deposited. FIGS. 35B and 35C show illustrative embodiments of such a non-conventional MIM structure, without a MIM top plate and a SiN layer with RI of 2.5. Compared to FIG. 35B, the MIM structure in FIG. 35C is absent of IMD layer 3504. The variable capacitance is obtained by moving plate M(x) towards plate M(x+1) to change distance d. This results in change in capacitance, Cᵥₐᵣ. The SiN layer 3512 in FIG. 35C may serve as a MIM dielectric in the ON state, obtaining a MAM (metal-air-metal) structure in the OFF state (low capacitance) and a MIM in the ON state (high capacitance) (M(x+1) collapsed over SIN layer), resulting in a high capacitance ratio. In embodiments with a SiN layer thickness of 60 nm, a capacitance density of 1 fF/um² may be obtained for the ON state using SiN as the dielectric for the MIM. The ON state MAM may also be implemented using a SiN layer as a top plate stopper. In embodiments with SiN layer stoppers of 60 nm, a capacitance density of 0.15 fF/um² may be obtained. A MAM structure may allow for a better capacitor Q and lower switch insertion loss.

In some embodiments, a higher capacitance density may be obtained by using high-k dielectrics, such as Al₂O₃ or HfO₂ deposited using a Atomic Layer Deposition (ALD) technique. A MIM capacitive structure produced using ALD may achieve lower thickness than the Chartered MIM structure, as well as better capacitance density. A MIM capacitive structure with high-k dielectrics, Al₂O₃ or HfO₂, may have a very high capacitance density between 4.5 and 12 fF/um². An issue with high-k dielectric materials is their linearity (C(V)). However, linearity may not be an issue for capacitive switch implementations like those of FIGS. 33A and 33B. The symmetric layout of the switch may compensate for capacitance deviations due to applied voltage during the OFF state.

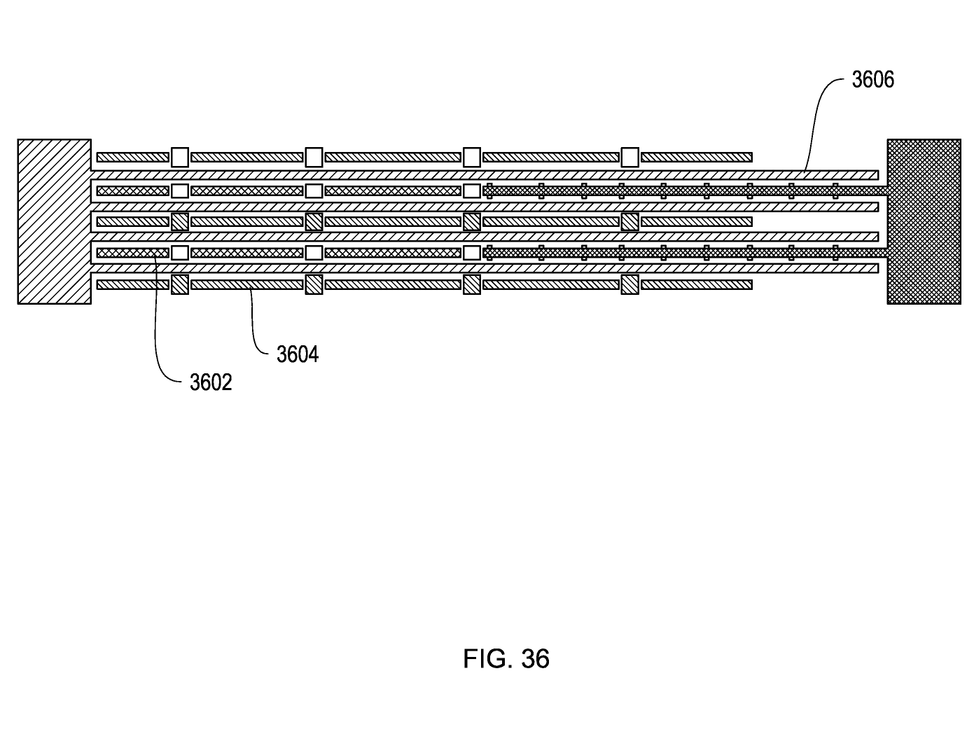

FIG. 36 shows an illustrative embodiment of a MIM capacitive structure with high-k dielectric deposited on vertical walls. This capacitive switch exhibits lateral displacement of capacitor plates. Compared to vertical displacement, lateral displacement allows for shorter distance between electrodes, which reduces actuation voltage. This configuration may avoid bending due to stress since a stack of three or four metal layers may be used. Additional benefits of lateral displacement include better alignment, better control of the OFF state capacitance, lower dielectric charging, and easier implementation of push/pull electrodes (to avoid self-actuation). The MIM capacitive structure in FIG. 36 comprises push electrodes 3602, pull electrodes 3604, and movable fingers 3606. Movable fingers 3606 may move laterally to vary capacitance of the structure. One finger may vary the capacitance from 2.75 fF to 295 fF, and may consume an area of 50×5 um². The capacitance may be reduced due to roughness and imperfect contact between the top electrode and the dielectric. This MIM structure exhibits a capacitance density of 0.3 fF/um², including the area for movable fingers and electrodes.

### Mechanical Capacitor

While the foregoing describes one or more MEMS devices arranged using one more an integrated circuit fabrication techniques that may be employed for various types of applications, the applications discussed below should not be considered as limited to this type of process. The foregoing is one type of process to implement the applications given below.

In order to achieve large inductor or capacitor values, and/or high quality factors, passive components generally need to be bulky. When fabricated, the components may consume a large amount of die space. Alternatively, the components may be placed off-chip. Both techniques may result in high costs, and in some instances, fabrication may not even be possible. Therefore, it may be advantageous to integrate on-chip monolithically large inductors and capacitors with high quality values, but without increasing their required die area. Such components are referred to as “integrated passives”.

In some embodiments, MEMS technology may be used to build a “mechanical capacitor”. Additional requirements for the mechanical capacitor may comprise small size and fabrication in an integrated circuit. The mechanical capacitor comprises a MEMS structure that stores energy when a voltage difference is applied across it. In comparison with a conventional electrical capacitor, a mechanical capacitor may store and release energy with little change in voltage across the device. A mechanical capacitor may provide large tangent capacitances and very low secant capacitances.

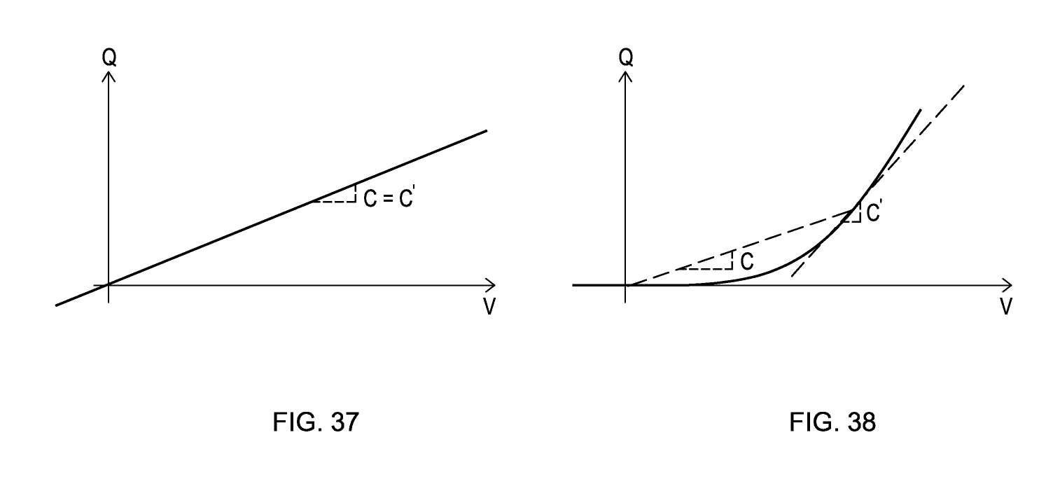

FIGS. 37 and 38 illustrate tangent and secant capacitances. If a voltage difference V is applied across a capacitor, each of its plates may be charged with a total charge of Q. The function of this charge Q, depending on the voltage V across the plates, may be defined as Q(V). This may be a linear function as shown in FIG. 37.

The capacitance secant capacitance C is defined as:

$$C = \frac{Q}{V}$$

The tangent capacitance C′ is defined as:

$${C}^{′} = \frac{d Q}{d V}$$

For an electrical capacitor, both capacitances are equal, i.e., C=C′. Hence, no distinction need be made in between the secant and the tangent capacitances. In a mechanical capacitor, however, Q(V) may be a non-linear function of the type shown in FIG. 38. Consequently, a distinction may exist between the secant capacitance C and the tangent capacitance C′.

In some embodiments, a mechanical capacitor may provide large tangent capacitances and very low secant capacitances. A high tangent capacitance value for a mechanical capacitor may allow for reduced output voltage ripple while delivering large currents to the load. A low secant capacitance for the mechanical capacitor may reduce power wasted while charging the capacitors when the input raw voltage changes. A low secant capacitance may be further advantageous since the capacitor only needs to store a small charge, leading to a smaller capacitor size compared to an electrical capacitor.

Switched capacitor converters may be used for conversion of DC voltages. Basic switched converters generally provide one simple voltage conversion. The most common applications for these circuits are to provide a single output voltage signal that is a doubled, halved or inverted form of the an input voltage signal. In some embodiments, a mechanical capacitor may be combined with a switched capacitor converter (SCC) to form an extremely efficient power supply. Such a power supply may deliver large currents while being fully integrated in a single integrated circuit, without need for any external components. The power supply may be fed with multiple power sources, and may deliver a desired output voltage. In some embodiments, the power supply may allow for dynamically changing the output voltage. The mechanical capacitor may allow for high efficiency values for the power supply, even when the input voltage is changing. Such a feature may be aid in implementing a power amplifier. Additionally, the power supply may be used inside Flash memories, where high amplitude voltage pulses of varying levels may be required.

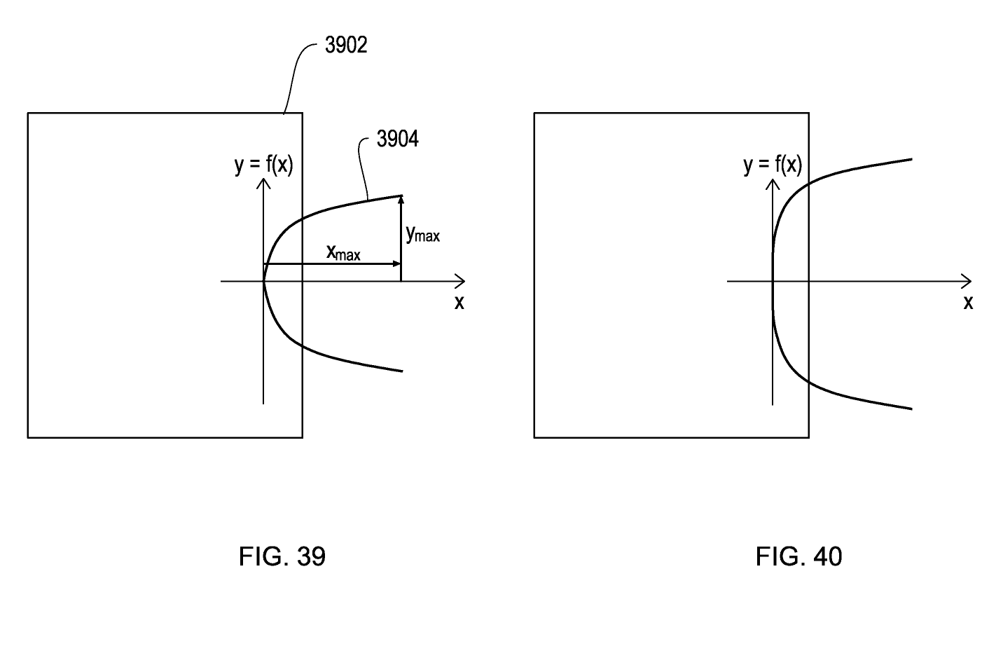

FIG. 39 shows an illustrative schema for a lateral mechanical capacitor design. In the lateral design, the device comprises a parallel plate capacitor, where one plate 3902 is fixed, and the other plate 3904 moves laterally by means of spring structures. The shape of the plate may define the stability and the tangent capacitance, and may be controlled. In some embodiments, the mechanical capacitor comprises two horizontal plates, where one plate may be fixed, and the other may be restricted in two directions and allowed to move in one direction only. In some embodiments, the moveable plate may move by means of one or more springs. In some embodiments, the moveable plate may be placed with a horizontal position tangent to the fixed plate. In some embodiments, the moveable plate may be initially placed with some overlap with the fixed plate (like shown in FIG. 39).

If a very low voltage is applied across the mechanical capacitor, the mechanical force implemented by means of a spring-like structure may be very small. In such a case, the mechanical capacitor may behave like an electrical capacitor. The moveable plate may be submitted to a electrostatic force and a mechanical restoring force. In the equilibrium position, these forces may be equal. However, if the voltage applied across the device is increased, the electrostatic force may increase causing movement of the moveable plate of the mechanical capacitor. In some embodiments, the mechanical capacitor may be designed such that plate movement either diminishes the electrostatic field or the distances between the capacitor plates, or both. Since the mechanical movement may diminish the voltage, it may be difficult for the voltage to increase. A change in position of the moveable plate may increase the mechanical restoring force, which may be stored as mechanical potential energy in this spring. A change in position of the moveable plate back to its initial position may convert the mechanical potential energy back to electrical energy. FIG. 39 shows the direction of movement as the x direction. The shape of the moveable plate is defined by f(x), being symmetrical for they direction. This shape may be defined easily and precisely in the layout of the process. The movement may be performed either by shaped plate 3904 or rectangular plate 3902.

The mechanical capacitor moveable plate may be built with a potential shape function, for example, potential shape function 3904 (FIG. 39). The maximum vertical distance yₘₐₓ and the maximum lateral displacement xₘₐₓ are related, according to:

yₘₐₓ=Bxₘₐₓⁿ,

where xₘₐₓ and yₘₐₓ define the horizontal and vertical sizes of the moveable plate, as shown in FIG. 39. Hence,

$$B = \frac{{y}_{max}}{{x}_{max}^{n}} ,$$

and mechanical restoring force k may be calculated as:

$$k = \frac{ɛ {V}_{0}^{2} {y}_{max}}{{gx}_{max}} ,$$

where Vₒ is the operating voltage, ∈ is the free space permittivity ∈ₒ, and g is the gap distance between the two capacitor plates. In one embodiment, the following values may be used:

$$\{ \begin{matrix}ɛ = {ɛ}_{0} = 8.85 \cdot {10}^{- 12} F \text{/} m \\ g = 1 µm \\ {x}_{max} = 10 µm \\ {y}_{max} = 10 µm \\ {V}_{0} = 1 V\end{matrix}$$

Using these values, mechanical restoring force, k=8.85·10⁻⁶ N/m≈10⁻⁵ N/m, which is a very low k value. k may be increased by means of increasing Vₒ, increasing the yₘₐₓ/xₘₐₓ ratio, or increasing gap distance g.

In some embodiments, the mechanical capacitor may be split into a plurality of smaller capacitors that are connected in parallel. If the plurality occupies the same area as the original capacitor, the final capacitance may be the same (both secant and tangent). This may be advantageous since it may be easier to build a plurality of devices, each with an area smaller than the original mechanical capacitor, than one single device with a large area. The plurality may allow for a narrow gap between the plates. However, the area of the plurality of devices may be larger than that of a single device if each requires its own springs. In some embodiments, damping is performed after a voltage change with the aid of an inert gas in contact with the device. In some embodiments, the operative frequency range of the mechanical capacitor may be below 1 MHz. In some embodiments, the mechanical capacitor may implemented with very small structures, e.g., nano structures, for an operative frequency above 1 MHz.

In some embodiments, the mechanical capacitor may be designed to take into account fringing fields. Fringing fields may be minimized with a very narrow gap between the two capacitor plates and a large overlap area. In some embodiments, the moveable plate may exhibit movement in the two restricted directions, parallel to the substrate. A change in the area of overlap may generate lateral forces to force movement of the plate. This effect may be minimized by designing springs to take into account the lateral forces. In some embodiments, the mechanical capacitor may be implemented to take into account the finite time response of the device. This may be advantageous when frequencies of the signals involved are high compared to the mechanical resonance frequency of the capacitor. In some embodiments, the mechanical capacitor may use a potential function approximated as a linear function with a vertical offset (FIG. 40). Such a design may require low values for the mechanical restoring force constant k. However, a mechanical capacitor with low k value may be sensitive to external accelerations, e.g., vibrations and rotations. Sensitivity may result in the device not working for a period of time because of an external acceleration. In some embodiments, a double structure may be constructed, each with its own springs. The mechanical capacitor may be placed inside first structure. If an external acceleration is performed on the whole device, the inner structure may oscillate. However, since the inner structure contains both the fixed plate and the moveable plate, their relative movement may be zero.

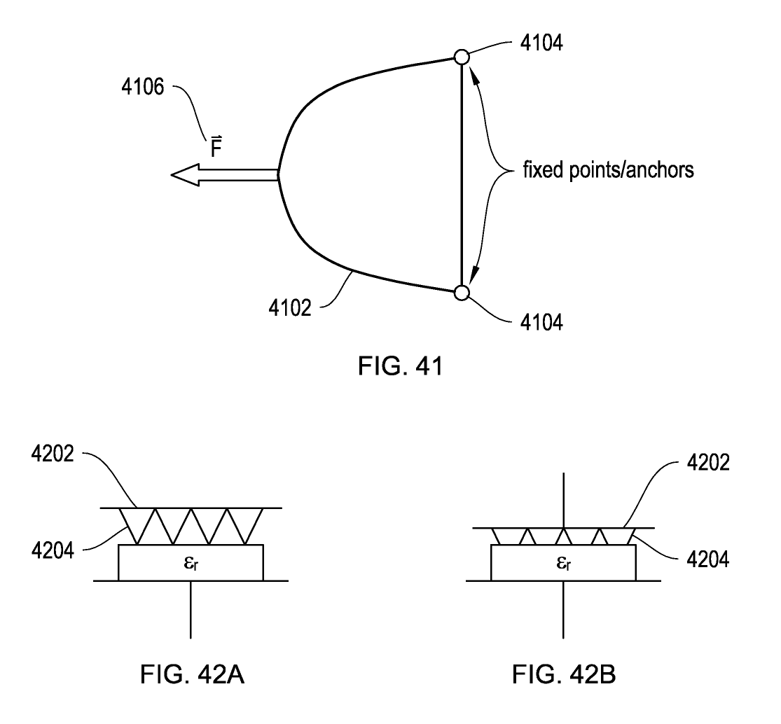

Alternative designs to the lateral mechanical capacitor design may be used. The different designs may be combined such that the final tangent capacitance increase with respect to the secant capacitance may be a product of each of the variants. FIG. 41 shows an illustrative design for a mechanical capacitor moveable plate. Moveable plate 4102 (e.g., plate 3904 in FIG. 39) may be stretched either by means of a thermal or electrostatic force 4106. The plate may be anchored by fixed points 4104. In some embodiments, the moveable plate may move longitudinally instead of laterally. However, the device may behave as a mechanical capacitor provided that the moveable plate is not moved more than, for example, ⅓ of the full traveling range. The lateral design may increase the capacitance by means of increasing the parallel plate capacitor area, and thus reducing the electric field. The longitudinal design may increase the capacitance by means of reducing the parallel plate capacitor distance, and hence reducing the voltage drop.

Another design alternative for a mechanical capacitor plate may involve the use of a dielectric with a high permittivity value instead of air. In some embodiments, a very thin gap may be produced with the aid of a metal with an isolator oxide, e.g., nickel. On oxidation the metal may form a very thin oxide layer, which may act as an isolator. If the moveable plate is allowed to perform a vertical movement when the electrostatic force is high, it may touch the isolating oxide, resulting in a very thin effective gap, i.e., the height of the dielectric layer. In some embodiments, the moveable plate may collapse and touch the oxide when the desired operative voltage is designed to be the same as the pull-in voltage. This may avoid excessive wear by reducing friction until the operative voltage is reached. In some embodiments, a tunable dielectric may be used. A tunable dielectric material exhibits varying dielectric permittivity with variation in applied voltage. If the dielectric permittivity increases with the applied voltage, it may be used to form a mechanical capacitor.

FIG. 42A shows a mechanical capacitor design where the moveable plate 4202 comprises a set of deformable dimples or tips 4204. The dimples may be soft enough to deform when the two capacitor plates touch, as shown in FIG. 42B. This may reduce the effective gap distance when the applied voltage increases, thus increasing the secant and tangent capacitances. In some embodiments, the fixed plate may comprise a set of deformable dimples or tips.

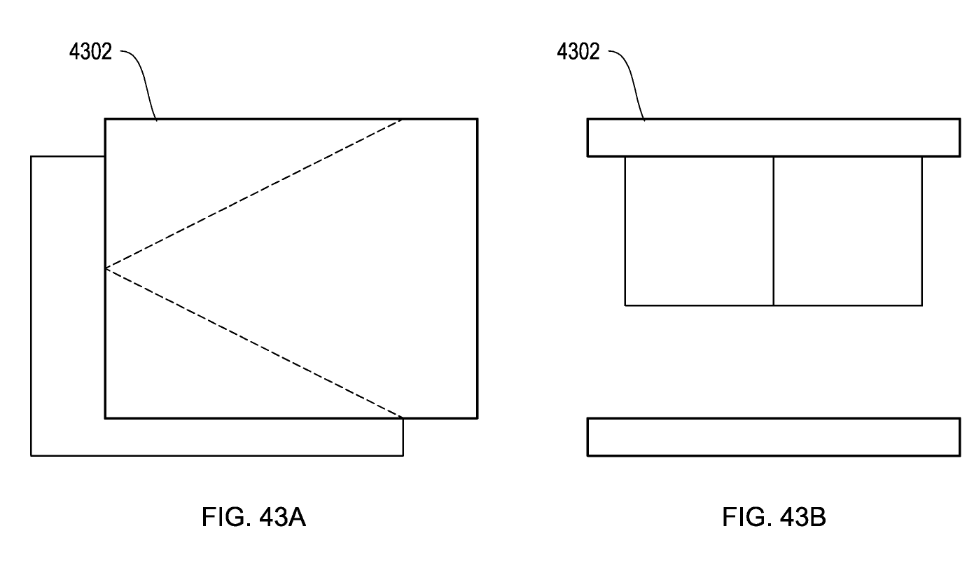

In some embodiments, a mechanical capacitor moveable plate (or the fixed plate or both) may increase in thickness with the lateral displacement x. For example, FIGS. 43A and 43B show top and lateral views of a variable gap mechanical capacitor with moveable plate 4302 of varying thickness. In a lateral design, displacement of the moveable plate may reduce the effective gap between the plates. Therefore, when voltage is applied to the mechanical capacitor, the area may be increased and the gap may be diminished, both at the same time. The combination of these two effects may lead to a larger value for the tangent capacitance.

In some embodiments, a mechanical filter device similar to a mechanical capacitor may be formed. A mechanical capacitor tries to accumulate a large charge Q, while a mechanical filter tries to keep the voltage V constant, regardless of changes in Q. Mechanical filters may used as voltage regulators and low frequency filters. In some embodiments, low frequencies of operation (below 1 MHz) of the device may restrict its use to frequencies below the mechanical resonance frequency. In some embodiments, mechanical filters may be extended to higher frequencies with conventional technologies. In some embodiments, a mechanical filter comprises a conventional MEMS electrostatic actuator with two parallel plates. The plates may form a capacitor C having an overlapping area A, separated by a distance g, where at least one of them is suspended with springs having an overall stiffness k. Application of a voltage V between the two plates may charge the capacitor C. This may result in an electrostatic force, moving the plates closer to a distance x, and injecting a total charge Q into the capacitor. In the equilibrium position, the mechanical restoring force may b defined as:

$$kx = \frac{ɛ}{2} \frac{{AV}^{2}}{{( g - x )}^{2}} ,$$

and the voltage may be defined as:

$$V = \frac{Q}{C} = \frac{Q ( g - x )}{ɛ A} .$$

Given the mechanical restoring force, the voltage may be redefined as:

$$V = \frac{Q}{ɛ A} ( g - \frac{{Q}^{2}}{2 ɛ Ak} ) .$$

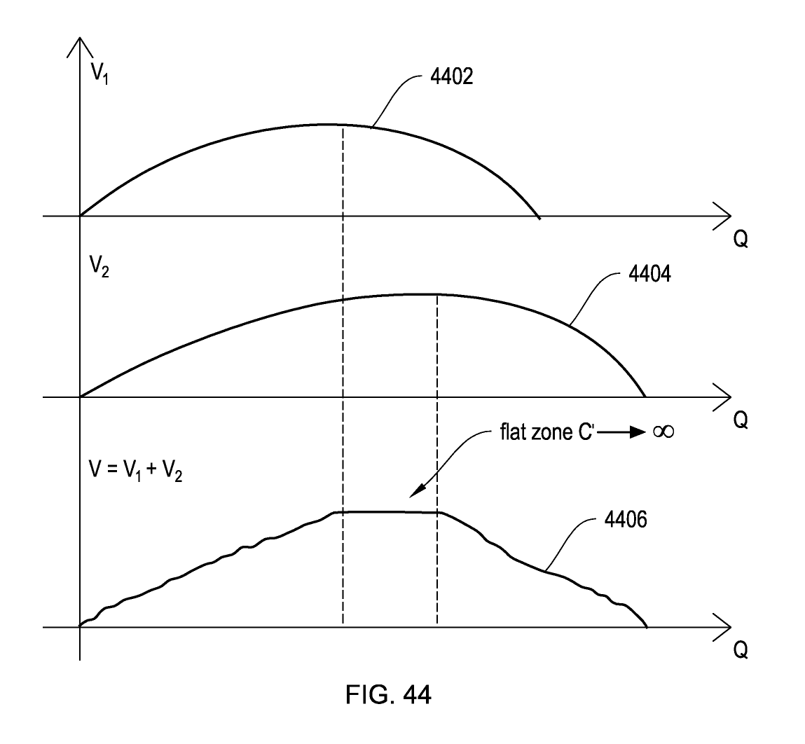

FIG. 44 shows the shape 4402 of voltage Vas a function of charge V(Q). The voltage V increases with charge Q until it reaches a maximum value (the pull-in voltage), which corresponds to plate position x=g/3 (using planar capacitors plate approximation). After this limit point, more charge lowers the voltage. In order to keep the device stable, the voltage may need to be lowered. The behavior prior to the limit point results in a positive slope, and seems similar to that of an electric capacitor. However, following the limit point, the behavior of the device results in a negative slope.

In some embodiments, two such devices may be connected in series, with proper designs and initial polarization, such that one is working with positive slope and the other with negative slope. This may result in a range of values for charge Q for which voltage Vmay be almost constant, resulting in a large tangent capacitance. The effect may be further enhanced with a plurality of devices in series. Curve 4406 (FIG. 44) shows an illustrative example of such an effect. Curves 4402 and 4404 may correspond to devices with charges Q₁ and Q₂, and voltages V₁ and V₂, respectively. Since the devices are connected in series, voltage V=V₁+V₂, and charge Q=Q₁=Q₂. Curve 4406 exhibits an almost flat zone where the tangent capacitance may be high, despite of low secant capacitance. In some embodiments, a very low slope may be achieved for a certain range of Q using several devices in series.

### Exponential Charge Pump

In some embodiments, a exponential charge pump with improved power efficiency and reduced area requirements may be implemented as a MEMS device. The exponential charge pump may comprise N stages, each of which raises the voltage by some charge, thus “pumping” the charge towards high voltage. Compared to a conventional charge pump where the voltage is raised by a fixed quantity in each stage, the MEMS exponential charge pump voltage is multiplied by a fixed quantity. Therefore, the voltage gain achieved may be exponential with the number of stages N, compared to linear voltage gain in a conventional charge pump. Reducing the number of stages may provide at least two advantages. Firstly, the overall capacitance required may be small, since each stage requires its own capacitance. As a result, the area may be small as well. Secondly, the charge may travel through a reduced number of p-n junctions. This may result in higher power efficiencies since p-n junctions are significant sources of losses.

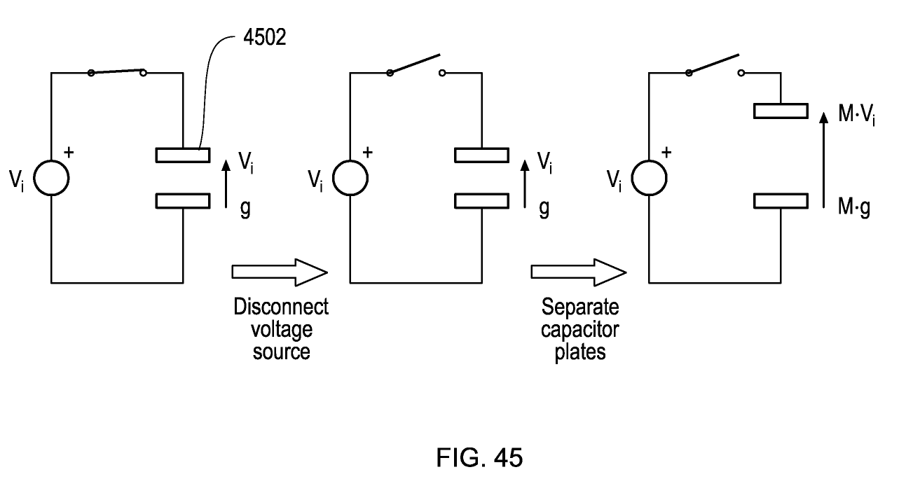

FIG. 45 illustrates the functioning of an exponential charge pump. A planar capacitor 4502 may be filled with some charge from source Vᵢ, putting it at a given voltage Vᵢ. Then the voltage source may be disconnected and plates separated from distance g to M·g. This may result in a rise in the voltage of the charge stored in the capacitor by a factor M. Similarly, a reduction in voltage may be achieved by reducing plate separation.

In some embodiments, an exponential charge pump may comprise an actuation capacitor, a pumping capacitor, a mechanical spring, and an output capacitor to collect the voltage. The capacitor plates may initially be joined by means of an electrostatic actuation, thus accumulating mechanical force in the spring. The plates may be initially joined to achieve a larger multiplying factor. The initial gap may need to be small since it may be difficult to move the plates vertically due to process limitations. Voltage may be applied across the close capacitor plates, and then the electrostatic actuation may be released. As a result, the capacitor plates may be separated again towards their initial position, thus multiplying the voltage. In this process, the electrostatic actuation energy may first be transferred towards the mechanical spring, storing it as a mechanical energy, and then transferred to the pumping capacitor, converting it to electrical energy again to be transferred to the output capacitor.

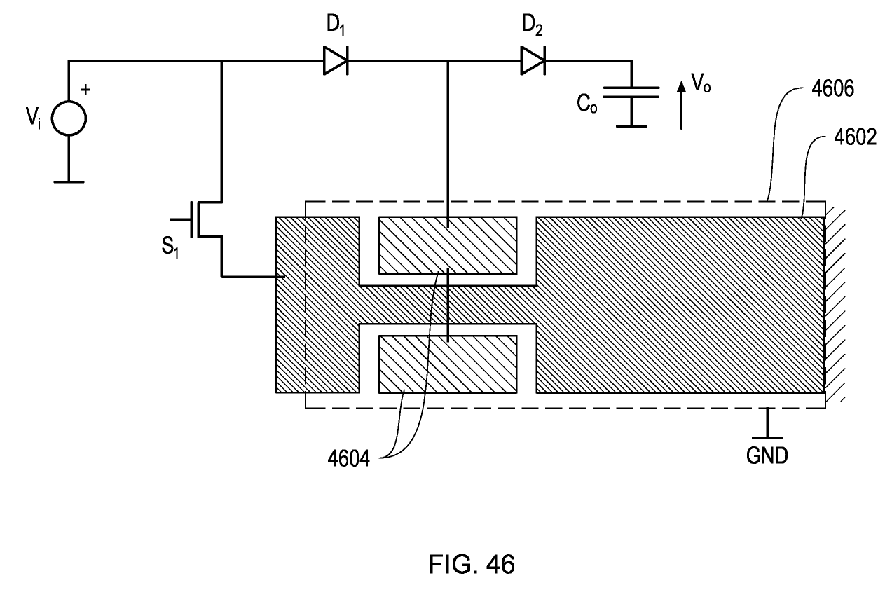

FIG. 46 shows an illustrative embodiment of an exponential charge pump, implemented with two layers. Electrode 4602 comprises the actuation electrode, and electrodes 4604 are shorted to form one plate of the pumping capacitor. All electrodes are located at the same level. On top (or bottom) of electrodes 4602 and 4604 is situated moveable cantilever 4606 (represented by a dashed line in FIG. 46), which is anchored at one end (the right end in FIG. 46). Moveable cantilever 4606 is electrically grounded at all times. In some embodiments, the mechanical resonance frequency of cantilever 4606 may be much higher than the time constant to fill the capacitor. When S₁ is turned on, actuation electrode 4602 is charged. Once actuation electrode 4602 is charged, S₁ is turned off to avoid sinking more charge from the source Vᵢ when cantilever 4606 approaches actuation electrode 4602 in the next step. In some embodiments, the mechanical resonance frequency of cantilever 4606 may not be much higher than the time constant to fill the capacitor. In this case, S₁ may turned on for a fixed and small period of time to limit charge sunk by actuation electrode 4602. Sunk charge may not be transferred to the pumping capacitor, and may be lost by means of thermal dissipation and shock of cantilever 4606 with actuation electrode 4602 and the air.

Moveable cantilever 4606 may bend towards actuation electrode 4602. Since the voltage source Vᵢ has been disconnected, the voltage between cantilever 4606 and actuation electrode 4602 may diminish while these plates approach themselves. Eventually, if they touch, the voltage difference may reach zero. While this voltage and the electrical energy E_{E} stored in the capacitor are diminishing, the electrical energy may be transferred to the spring and accumulated as mechanical energy E_{K}. The electrical energy E_{E} may be calculated as:

$${E}_{E} = \frac{1}{2} {C}_{a} {V}_{a}^{2} = \frac{1}{2} \frac{{Q}_{a}^{2}}{{C}_{a}} ,$$

where Cₐ is the actuation capacitor, Vₐ is the actuator voltage, and Qₐ is the actuator charge. Since the gap of the actuation capacitor may be diminished approximately by factor M, the variations in the voltage and capacitance may be calculated as follows, while the charge remains unchanged:

$${C}_{a final} = M \cdot {C}_{a} , \\ {V}_{a final} = \frac{{V}_{a}}{M} ,$$

where C_{a final} and V_{a final} are the final actuator capacitance and voltage respectively, once cantilever 4606 almost touches actuator electrode 4602.

Cantilever 4606 may either touch actuator electrode 4602, so that it discharges the actuator capacitor completely, or actuator electrode 4602 may be shorted to GND using another switch. It may be advantageous to have little energy left to dissipate, and to avoid shock of cantilever 4606 with actuation electrode 4602. Consequently, the pumping capacitor may be charged to Vᵢ through diode D₁. The pumping capacitor may be smaller than the actuator capacitor, and its plates may be located closer to the cantilever clamp, allowing for reduction in moment to be made for the same force. Since the electrostatic force may not overcome the mechanical restoring force of cantilever 4606, cantilever 4606 may return towards its initial rest position. As a result, the pumping capacitor voltage may be multiplied by a factor of M.

Once the pumping voltage reaches V₀, it may initiate filling the output capacitor C₀ towards diode D₂, while cantilever 4606 keeps moving upwards. Once cantilever 4606 has returned to its initial position, the process may be repeated again in a periodic manner. The pumping frequency may be adjusted to the load current consumption, or the device may be turned on and off at each moment according to the load power needs. If the voltage needs to be raised by a factor greater than may be achieved by one stage, several stages may be cascaded, where the output voltage V₀ of one stage may be the input voltage Vᵢ of the next stage. Therefore, cascading N stages, each stage with a voltage gain of M, may result in an overall voltage gain of M^{N}.

The power efficiency η of the exponential charge pump described in FIG. 46 may be limited by diode D₁. A first estimation of the power efficiency may be calculated as:

$$η < \frac{{V}_{i} - {V}_{D}}{{V}_{i}} = 1 - \frac{{V}_{D}}{{V}_{i}} ,$$

where V_{D} is the voltage drop across D₁. In some embodiments, efficiency η may be improved by using MOSFETs to simulate the diodes. Such a process is referred to as synchronous rectification, and comprises turning the MOSFETs on and off as required at each moment.

### Integrated Steerable Antenna for Wireless

In some embodiments, antennas may be integrated inside a MEMS integrated circuit. However, integration may not allow for proper orientation of the antenna. A technique known as multiple-input and multiple-output (MIMO) comprising the use of multiple antennas at both the transmitter and receiver may be used for orientation and improved communication performance, but may consume a large amount of die space. In some embodiments, a MEMS integrated antenna that is steered mechanically may be used. A bi-dimensional array may further increase the gain of the antenna, while the use of fractal antennas may provide multi-band capability. In some embodiments, the mechanically steerable integrated antenna may be fabricated in the interconnection layers of a MEMS integrated circuit. The antenna may be implemented in a wireless USB transceiver. Since the antenna may be steered mechanically, a user of the device need not move the antenna in order get good reception.

Applicant considers all operable combinations of the embodiments disclosed herein to be patentable subject matter. Those skilled in the art will know or be able to ascertain using no more than routine experimentation, many equivalents to the embodiments and practices described herein. Accordingly, it will be understood that the invention is not to be limited to the embodiments disclosed herein, but is to be understood from the following claims, which are to be interpreted as broadly as allowed under the law. It should also be noted that, while the following claims are arranged in a particular way such that certain claims depend from other claims, either directly or indirectly, any of the following claims may depend from any other of the following claims, either directly or indirectly to realize any one of the various embodiments of the invention.

What is claimed is:

1. A method for manufacturing a chip comprising a MEMS arranged in an integrated circuit comprising:
producing layers, in one or more stages, that form electrical and/or electronic elements on a semiconductor material substrate,
producing a structure of interconnection layers, during an interconnection stage, comprising depositing at least one bottom layer of conductor material and one top layer of conductor material, separated by at least one layer of dielectric material, the at least one bottom layer of conductor material including a bottom layer of conductor material formed above and in contact with an Inter Level Dielectric (ILD) layer, and
forming at least one hollow space of the MEMS in the structure of interconnection layers using gaseous HF during an attack stage, the MEMS being formed above the bottom layer of conductor material in contact with the ILD layer.

2. The method according to claim 1, wherein the top layer of conductor material comprises a plurality of holes sized to allow the gaseous HF pass through and inhibit nitrides from passing through.

3. The method according to claim 2 comprising forming the plurality of holes such that a portion is aligned above the MEMS.

4. The method according to claim 2, wherein a hole in the plurality of holes has a diameter less than or equal to 100 nm, 200 nm, 300 nm, 400 nm, or 500 nm.

5. The method according to claim 2, wherein additional stages are carried out between the interconnection stage and the attack stage, the additional stages comprising:
forming a passivation layer during a production stage, wherein the passivation layer comprising a bottom layer of silicon dioxide and a top layer of silicon nitride arranged on top of the top layer of conductor material, and
removing, at least partially, the passivation layer during a removal stage.

6. The method according to claim 5, comprising forming an ALD coating during an ALD coating stage after the attack stage.

7. The method according to claim 6, wherein the MEMS comprises a mobile element that is moved during the ALD coating stage.

8. The method according to any of the claim 5, further comprising a stage of producing a sealing layer.

9. The method according to claim 8, wherein the top layer of conductor material undergoes an ALD coating before the stage of producing the sealing layer.

10. The method according to claim 5, wherein the stage of at least partially removing the passivation layer produces openings that are arranged over plates of conductor material belonging to the top layer of conductor material, and comprising a stage of producing a sealing layer to fill, at least partially, the hollow space between each of the openings and the corresponding plate of conductor material.

11. The method according to claim 1 comprising:
establishing at least one direct interconnection between the substrate and at least one of the layers of conductor material by means of an HF resistant material.

12. The method according to claim 11, wherein a layer of amorphous silicon exists between the substrate and the conductor material.

13. The method according to claim 12, wherein the MEMS comprises a conductor element including a movable part.

14. The method according to claim 13, wherein the MEMS comprises at least two capacitor plates arranged to produce electrostatic fields over the movable part that are capable of moving the movable part.

15. The method according to claim 14, wherein the MEMS operates as a relay, the MEMS comprising at least two contact points in an electric circuit arranged to allow the movable part to be in contact simultaneously with both contact points.

16. The method according to claim 1, wherein the MEMS comprises a device including at least one of an electrical relay, accelerometer, inclinometer, Coriolis force detector, pressure sensor, microphone, flow rate sensor, temperature sensor, gas sensor, magnetic field sensor, electro-optical device, optical switching matrix, image projector device, analogue connection matrix, electromagnetic signal emission and/or reception device, power supply, DC/DC converter, AC/DC converter, DC/AC converter, A/D converter, D/A converter, and power amplifier.

17. A chip comprising an integrated circuit, said integrated circuit comprising:
one or more layers forming electrical and/or electronic elements on a substrate of semiconductor material,
a structure of interconnection layers comprising at least one bottom layer of conductor material and one top layer of conductor material, separated by at least one layer of dielectric material, the at least one bottom layer of conductor material including a bottom layer of conductor material formed above and in contact with an ILD layer, and
at least one MEMS arranged in the structure of interconnection layers, wherein the MEMS comprises at least one hollow space, and a portion of the hollow space is arranged over the bottom layer of conductor material in contact with the ILD layer.

18. A method for manufacturing a MEMS integrated circuit comprising:
producing layers, in one or more stages, that form electrical and/or electronic elements on a semiconductor material substrate,
producing a structure of interconnection layers, during an interconnection stage, comprising depositing at least one bottom layer of conductor material and one top layer of conductor material, separated by at least one layer of dielectric material, the at least one bottom layer of conductor material including a bottom layer of conductor material formed above and in contact with an Inter Level Dielectric (ILD) layer,
producing a vias extending continuously across at least two layers of the plurality of layers,
using gaseous HF to form a hollow space in the structure of interconnection layers, and
forming at least a portion of a MEMS device within the structure of interconnection layers.

19. The method of claim 18 comprising stacking the plurality of layers together to form an equivalent thicker metal layer joined by a plurality of vias.

20. The method of claim 18 comprising attaching the MEMS device to the structure of the interconnection layers via a soft spring comprised of one or more metal layers joined by a plurality of vias.

21. The method of claim 18 comprising forming the MEMS device which comprises a part that is detached from the MEMS structure and is mechanically free.

22. The method of claim 18 comprising adding a partition of HF resistant material around the MEMS device, wherein the partition of HF resistant material comprises the continuous vias.

23. The method of claim 18 wherein the MEMS device comprises a multi-level memory programmable by changing the resistance value of a via in a cell of the memory by overpassing the electromigration limit for a limited period of time.

24. The method of claim 18 comprising producing a passivation layer in the structure of interconnection layers.

25. The method of claim 24 further comprising performing chemical-mechanical polishing on the passivation layer.

26. The method of claim 18 comprising:
manufacturing the MEMS integrated circuit on a wafer, and
performing passivation on a plurality of scribe lines of the wafer.

27. The method of claim 18 comprising producing the at least one layer of dielectric material which comprises a double oxide.

28. The method of claim 18 comprising producing the at least one layer of dielectric material which comprises a single oxide.

29. The method of claim 18 wherein producing the structure of interconnection layers comprises producing:
a top layer of conductor material having a plurality of holes, arranged over the MEMS device; and
a following layer of conductor material having a plurality of holes that are not aligned with the holes of the top layer of conductor material, arranged under the top layer of conductor material.

30. The method of claim 29 comprising:
depositing a passivation layer on the top layer of conductor material, the passivation layer comprising a bottom layer of silicon dioxide and a top layer of silicon nitride,
releasing vaporized HF to etch away the dielectric material separating the layers of conductor material, and
sputtering Al on the passivation layer.

31. The method of claim 29 comprising:
depositing a film of photoresist material on the passivation layer,
removing a portion of the film to form a photoresist mask on the sputtered Al on the passivation layer,
etching away the sputtered Al material not under the mask from the sputtered Al layer, and
removing the photoresist mask to release an Al plugged area.

32. A MEMS integrated circuit comprising:
a plurality of layers, a portion of which includes one or more electronic elements on a semiconductor material substrate,
a structure of interconnection layers including a bottom layer of conductor material and a top layer of conductor material, separated by at least one layer of dielectric material, the bottom layer of conductor being formed above and in contact with an ILD layer,
at least one vias extending continuously across at least two layers of the plurality of layers,
a hollow space in the structure of interconnection layers, and
a MEMS device in communication with the structure of interconnection layers.
